(19) United States
(12) Patent Application Publication
(10) Pub. No.: US 2005/0073530 A1
(43) Pub. Date: Apr. 7, 2005

(54) System and method for display calibration

(76) Inventors: Jay Kapur, Redmond, WA (US); Mark Schwesinger, Redwood City, CA (US); Joel Silver, Boca Raton, FL (US)

Correspondence Address: LEE & HAYES PLLC, 421 W RIVERSIDE AVENUE SUITE 500, SPOKANE, WA, 99201, US

(21) Appl. No.: 10/678,485

(22) Filed: Oct. 3, 2003

(51) Int. Cl. G09G 5/02; G09G 5/00; G03F 3/08; H04N 1/46; H04N 17/00; H04N 9/12

(52) U.S. Cl. 345/594; 345/600; 345/213; 345/204; 358/521; 358/504; 348/180; 348/383; 348/179

(57) ABSTRACT

A system and method that enables a user to calibrate a display by presenting instructions to the user is described. This system and method can enable a user to calibrate a display by presenting instructions to the user that are based on the type or the connection type of display that the user is attempting to calibrate. It can also enable a user to more easily and intuitively calibrate his or her display by presenting a motion video tailored to help the user calibrate a parameter of the user's display.

### TECHNICAL FIELD

This invention relates to a system and method for calibrating displays.

### BACKGROUND

When a user views video on a television or other video display, the video sometimes does not look quite right. This is not a new problem, as televisions for decades have often presented video that does not look like it is supposed to look. Sometimes the display is too red, bright, or fuzzy, for instance.

To address this problem, display designers typically build into displays various controls with which a user can calibrate parameters of the display. Televisions, for instance, typically have controls enabling a user to calibrate a television's brightness, color, and contrast parameters.

But users often found adjusting these parameters without assistance did not result in an optimally calibrated display. When users adjusted a parameter while watching a television program, for instance, the adjustment was hit-or-miss. A user attempting to adjust a display's brightness, for instance, could turn it too high if the current video program was dark or even moderately dark (like programs set in the evening), or too low if the program were too bright (such as programs set in the outdoors during the day—like an outdoor sporting event). Further, when users adjusted a parameter on a computer display while viewing typical menus, computer graphics, and the like, the color was often difficult to accurately adjust.

To aid users in adjusting their displays using these controls, various testing screens are currently provided. These testing screens are typically presented when a user attempts to adjust particular parameters of a display. They are often technical and computer-generated. To explain these technical testing screens, designers sometimes also provide explanations to users as to how the testing screen should look to optimize the display.

Even so, these testing screens can be hard for users to use and understand. Users can struggle with trying to figure out how to use a testing screen because it is technical and computer-generated. They can struggle, for instance, with trying to understand what the testing screen is supposed to look like in order to optimize the appropriate parameter. Further, users can struggle with relating how changes to a technical, computer-generated graphic relates to how the display will look when presenting realistic video.

Also, testing screens often are generic for all types of displays. This further complicates calibration for users by their needing to understand how a generic testing screen applies to their particular type of display.

For these reasons, users often find calibrating a display difficult and inconvenient.

### SUMMARY

The following description and figures describe a system and/or method (a “tool”) for aiding a user in calibrating a display. This calibration tool enables a user to more easily and intuitively adjust parameters of his or her display.

The calibration tool enables a user to calibrate a display by presenting instructions to the user that are based on the type and/or the connection type of the display that the user is attempting to calibrate. Using this tool, a user can view instructions based on his or her type of display. This helps the user because certain instructions are easier to follow and understand when directed at the user's display than to a generic display. A user can, for instance, view instructions directed to calibrating a Cathode Ray Tube (CRT) type of display.

The calibration tool also enables a user to more easily and intuitively calibrate his or her display by presenting a motion video tailored to help the user calibrate a parameter of the display. This motion video can be photo-realistic, rather than appear technical in nature, which is more intuitive to many users. Also, instead of requiring the user to understand how a technical and/or computer-generated testing screen should look to optimize his or her display, the user instead can use something he or she intuitively understands to do so. In addition, the motion video is moving, which further enables a user to more easily calibrate his or her display for viewing movies, television, and the like.

### BRIEF DESCRIPTION OF THE DRAWINGS

FIG. 1 illustrates a grid and cross-hatch test screen.

FIG. 2 illustrates a screen shot of an exemplary 4×3 centering and sizing motion video for aiding a user in calibrating a centering and sizing parameter of his or her display.

FIG. 3 illustrates a computer system capable of implementing a method for aiding a user in calibrating a display.

FIG. 4 is a flow diagram of a process for aiding a user in calibrating a display based on the user's type of display.

FIG. 5 is a flow diagram of an exemplary process for determining a user's type of display.

FIG. 6 illustrates a screen shot of an exemplary general display-type question menu with a traditional/CRT display-type graphic.

FIG. 7 illustrates a screen shot of an exemplary general display-type question menu with a flat-panel display-type graphic.

FIG. 8 illustrates a screen shot of an exemplary general display-type question menu with a rear-projection big-screen display-type graphic.

FIG. 9 illustrates a screen shot of an exemplary general display-type question menu with a front-projector display-type graphic.

FIG. 10 illustrates a screen shot of an exemplary shape question menu with a widescreen graphic.

FIG. 11 illustrates a screen shot of an exemplary connection-type menu with a television connection-type graphic.

FIG. 12 is a flow diagram of an exemplary process for tailoring instructions based on a user's type of display.

FIG. 13 illustrates an exemplary set of motion videos.

FIG. 14 illustrates one of two screen shots of an exemplary video explanation for centering and sizing motion videos.

FIG. 15 illustrates two of two screen shots of an exemplary video explanation for centering and sizing motion videos.

FIG. 16 illustrates a screen shot of an exemplary 16×9 centering and sizing motion video for aiding a user in calibrating a centering and sizing parameter of his or her display.

FIG. 17 illustrates one of two screen shots of an exemplary explanation of aspect-ratio motion videos.

FIG. 18 illustrates one of two screen shots of an exemplary explanation of aspect-ratio motion videos.

FIG. 19 illustrates a screen shot of an exemplary 4×3 aspect-ratio motion video for aiding a user in calibrating an aspect-ratio parameter of his or her display.

FIG. 20 illustrates a screen shot of an exemplary 16×9 aspect-ratio motion video for aiding a user in calibrating an aspect-ratio parameter of his or her display.

FIG. 21 illustrates one of two screen shots of an exemplary video explanation for a brightness motion video.

FIG. 22 illustrates two of two screen shots of an exemplary video explanation for a brightness motion video.

FIG. 23 illustrates a screen shot of an exemplary brightness motion video for aiding a user in calibrating an brightness parameter of his or her display.

FIG. 24 illustrates one of two screen shots of an exemplary video explanation for a contrast motion video.

FIG. 25 illustrates two of two screen shots of an exemplary video explanation for a contrast motion video.

FIG. 26 illustrates a screen shot of an exemplary contrast motion video for aiding a user in calibrating a contrast parameter of his or her display.

FIG. 27 illustrates one of two screen shots of an exemplary video explanation for an RGB color balance motion video.

FIG. 28 illustrates two of two screen shots of an exemplary video explanation for an RGB color balance motion video.

FIG. 29 illustrates a screen shot of an exemplary RGB color balance motion video for aiding a user in calibrating an RGB color balance parameter of his or her display.

FIG. 30 illustrates one of two screen shots of an exemplary video explanation for a color/tint motion video.

FIG. 31 illustrates two of two screen shots of an exemplary video explanation for a color/tint motion video.

FIG. 32 illustrates a screen shot of an exemplary color/tint motion video for aiding a user in calibrating an color/tint parameter of his or her display.

FIG. 33 illustrates one of two screen shots of an exemplary video explanation for a sharpness motion video.

FIG. 34 illustrates two of two screen shots of an exemplary video explanation for a sharpness motion video.

FIG. 35 illustrates a screen shot of an exemplary sharpness motion video for aiding a user in calibrating a sharpness parameter of his or her display.

FIG. 36 illustrates a screen shot of an exemplary display calibration menu.

FIG. 37 is a block diagram of a computer system that is capable of supporting display calibration.

The same numbers are used throughout the disclosure and figures to reference like components and features.

### DETAILED DESCRIPTION

The following disclosure describes an easy and intuitive aid for calibrating a display. This calibration tool is tailored to the type and/or the connection type of a display in use to better guide a user in calibrating the display. The calibration tool also can include photo-realistic motion videos, which are tailored to aid a user in calibrating a parameter of a display. Thus, the calibration tool guides a user in calibrating a display with photo-realistic motion video that is tailored to the user's display.

Introductory Example of an Old Test Screen and an Exemplary Motion Video

To aid the reader in understanding some of the context in which the calibration tool can be used, the following example is given. The example includes a currently used test screen and an exemplary motion video.

If a user wants to make sure that his display is properly adjusted to show objects at the right size and properly centered in his display, the user can adjust his display's centering and sizing parameters. Currently, many users adjust their displays with the aid of a grid and cross-hatch test screen. This test screen, like other currently used test screens, can be hard to use.

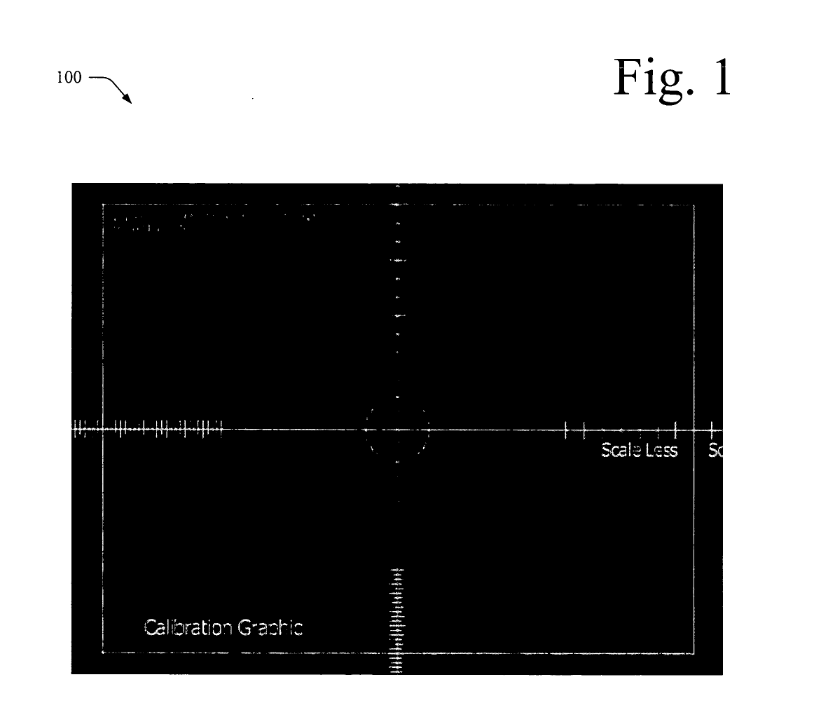

FIG. 1 sets forth a currently used grid and cross-hatch test screen 100 for aiding a user in adjusting the user's display. As can be seen in this figure, the grid and cross-hatch test screen 100 is not intuitive; it can be difficult for a typical user to figure out how it is supposed to work. Even after knowing how it is supposed to work, the user often has to relate this technical and unreal graphic test screen to what the user intends to view on the display, such as a live-action movie.

Also, the user may have to understand how that particular grid and cross-hatch test screen 100 should be used for his particular type of display. Assume, for this example, that the user's display has a standard shape (a 4×3 width-to-height ratio). This standard shape is found in many televisions and computer monitors. Another shape is also fairly common, the 16×9 width-to-height ratio, which is the shape at which many movies are shown. Because the grid and cross-hatch test screen 100 is not designed specifically for use with calibrating a 4×3-shape display, the user may have to figure out how to relate the test screen 100 to a 4×3-shaped display, which further complicates the user's attempt to calibrate his display.

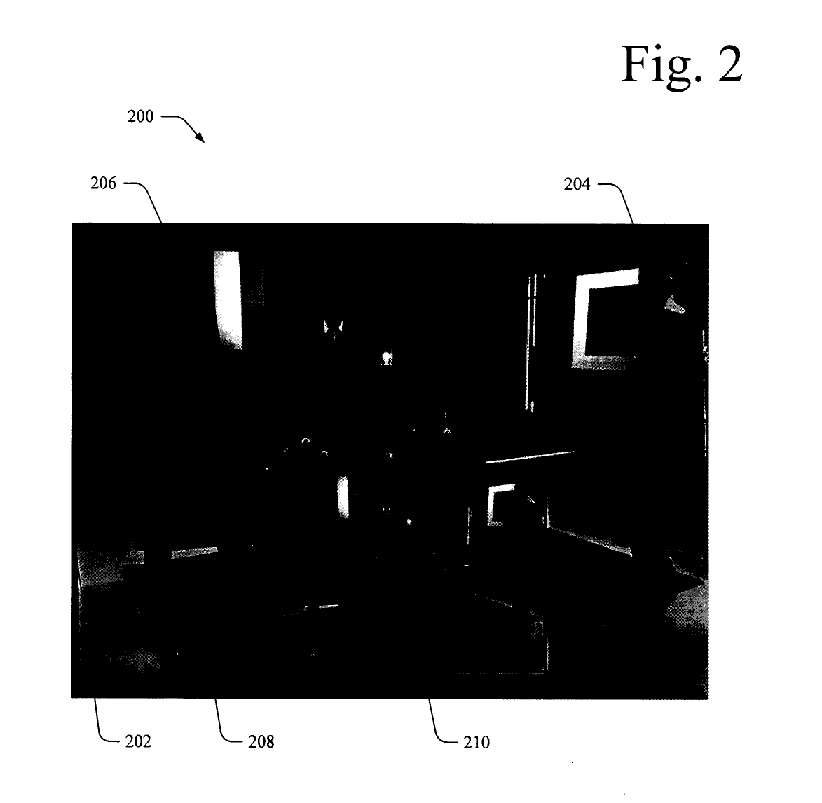

FIG. 2 sets forth a black-and-white screen shot of an exemplary standard-shape centering-and-sizing photo-realistic motion video 200. The standard-shape centering-and-sizing video 200 is designed for use with a display that has a 4×3 shape.

Continuing with our example, this standard-shape centering-and-sizing video 200 aids the user in calibrating his display because the video 200 is designed for the user's type of display. It is designed for standard-shape displays, which is what the example's user has.

The standard-shape centering-and-sizing video 200 also helps the user calibrate his display in an easy-to-use and intuitive way. First, the standard-shape centering-and-sizing video 200 is not intimidating or hard to understand because it shows real people and real objects.

Second, the video 200 helps the user calibrate his display's centering and sizing parameters by how it is structured. The video 200, even while showing people and objects in motion, has certain unmoving (or only slightly moving) objects to aid the user. Both of the pool cues, a left pool cue 202 and a right pool cue 204 are partially shown and very thin. This aids the user because if the user calibrates the display to show the video 200 slightly too large, the pool cues will disappear, even with a very slight calibration error. Likewise, the left pool cue 202 will disappear if the video 200 is only very slightly moved too far left by the user's centering calibration. Similarly, the right pool cue 204 will disappear if the video 200 is only very slightly moved too far right. Also, if the user calibrates the display only slightly too far up or down, a left woman's head 206 or a left woman's heels 208 will be cut off. As a more general aid, the video 200 shows users a small 4×3 video 210 that shows how their display should look when the centering and sizing parameters are optimized.

Thus, the video 200 is carefully tailored to aid the user in optimizing his display's centering and sizing parameters, while also being easy and intuitive to use.

With the reader now exposed to some of the context of the calibration tool, the discussion continues on to set some of the groundwork for a more thorough discussion.

The calibration tool, including motion videos, instructions, menus, explanations, and related processes can be implemented in computer and non-computer environments and with computer and non-computer systems. The calibration tool can, for instance, be implemented through MPEG DVDs, consumer set top boxes, satellite transmission, various broadcast sources, computer applications, and in other ways.

For discussion purposes, the calibration tool described herein is described in the environment of a single computer (including various applications), a user-input device, and a single display. The computer environment described is one implementation of a system capable of aiding a user in calibrating a display and is not intended to limit the applicability of the calibration tool disclosed herein.

The exemplary computer environment will be described below, followed by a discussion of the techniques in which the computer environment and other environments can be used to aid a user in calibrating a display.

Exemplary System

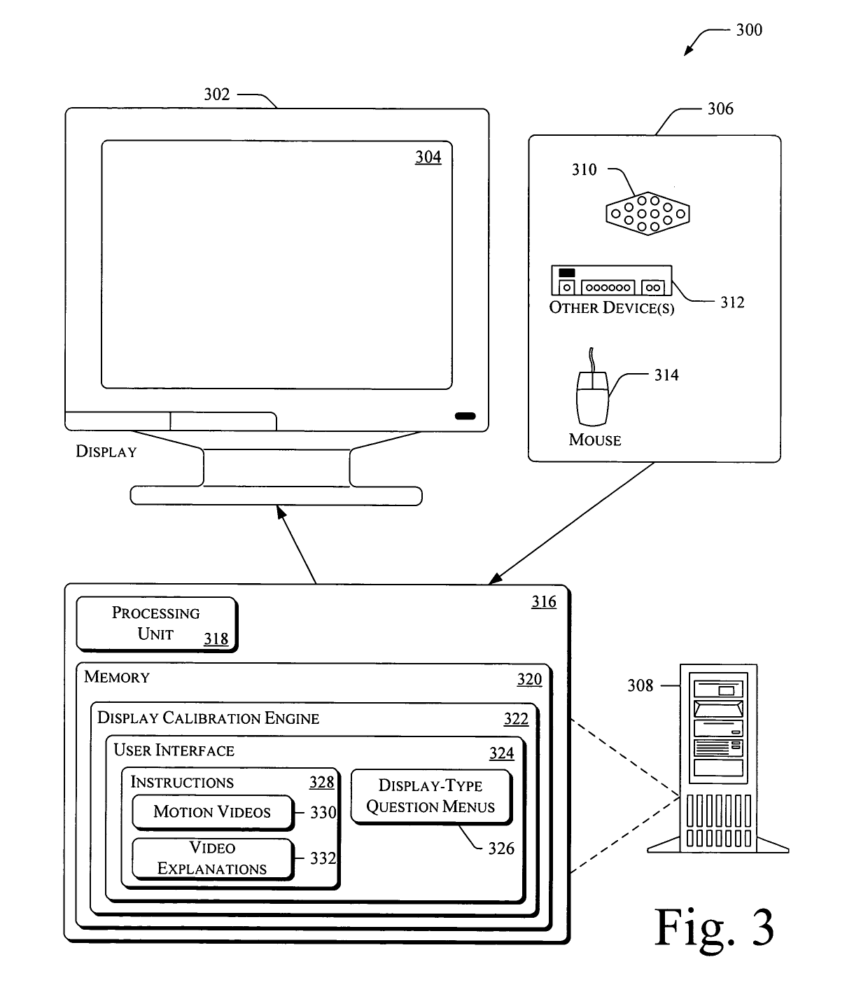

FIG. 3 shows an exemplary system 300 to help a user calibrate a display. The system 300 includes a display 302 having a screen 304, a user-input device 306, and a computer 308. The user-input device 306 can include any device allowing a computer to receive input from a user, such as a remote control 310, other devices 312, and a mouse 314. The other devices 312 can include a touch screen, a voice-activated input device, a track ball, a keyboard, and the like. The user can send input via the user-input device 306 to the computer 308 to select a type of display in use by the user. The user can use the display 302 and its screen 304 to view calibration menus, instructions, and motion videos.

The computer 308 includes components shown in block 316, such as a processing unit 318 to execute applications and a memory 320 containing various applications and files. The memory 320 includes any computer-readable media that can be accessed by the computer 308, and can be volatile and nonvolatile, removable and non-removable, or implemented in any method or technology for storage of information.

The applications in the memory 320 include a display calibration engine 322, which includes a user interface 324. The user interface 324 includes display-type question menus 326, instructions 328, motion videos 330, and video explanations 332.

The calibration engine 322 is configured to manage the user interface 324, including the display-type question menus 326, the instructions 328, the motion videos 330, and the video explanations 332. The calibration engine 322 determines which of the question menus 326 to show a user and the instructions 328 to present to the user. The instructions 328 can include the motion videos 330 and an explanation of how to use the motion videos 330 to calibrate a display with the video explanations 332.

The calibration engine 322 tailors the instructions 328 to present to a user based on the type and/or connection type of display that the user is attempting to calibrate. The calibration engine 322 can determine a type and a connection type of a display in use by the user through the user's response to the display-type question menus 326. How the calibration engine 322 manages the user interface 324, either singularly or as part of the system 300, will be discussed in greater detail below.

Techniques for Helping a User Calibrate a Display

Overview

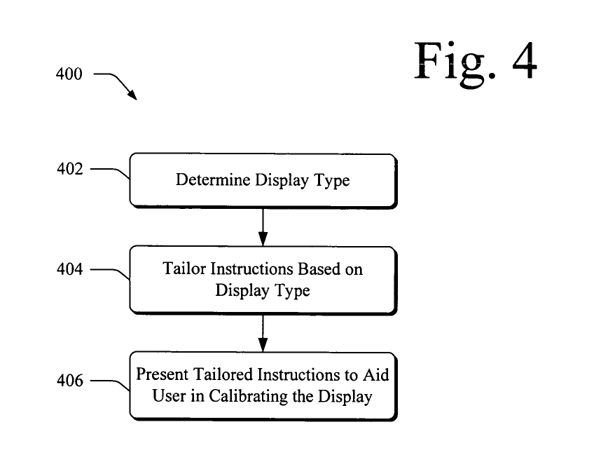

FIG. 4 shows a process 400 for helping a user calibrate a display based the user's display. The process 400 and other processes set forth herein are illustrated as series of blocks representing individual operations or acts performed by the system 300. These processes may be implemented in any suitable hardware, software, firmware, or combination thereof. In the case of software and firmware, they represent a set of operations implemented as computer-executable instructions stored in memory and executable by one or more processors.

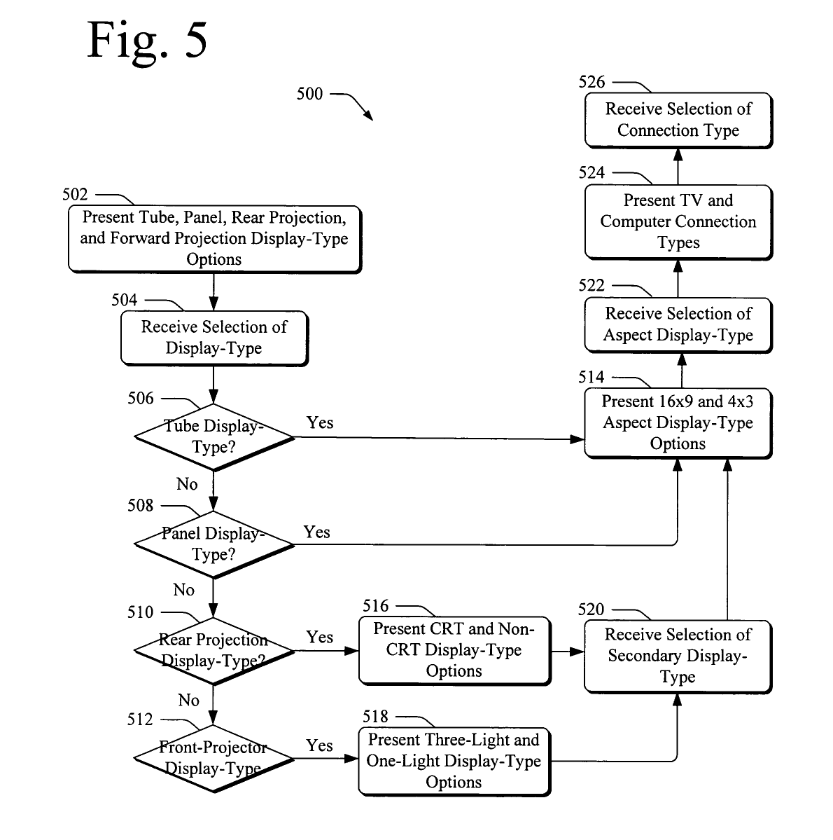

At block 402, the system 300 determines what type (and/or connection type) of display a user is attempting to calibrate. The system 300 can determine a user's display and connection type with help from the user. It can, for instance, present multiple types of displays to a user from which the user can select his or her type of display. An exemplary implementation of block 402 is shown in FIG. 5, which will be described below.

At block 404, the system 300 tailors the instructions 328 based on the user's display type and/or connection type. These instructions 328 are tailored to aid the user in calibrating his or her display.

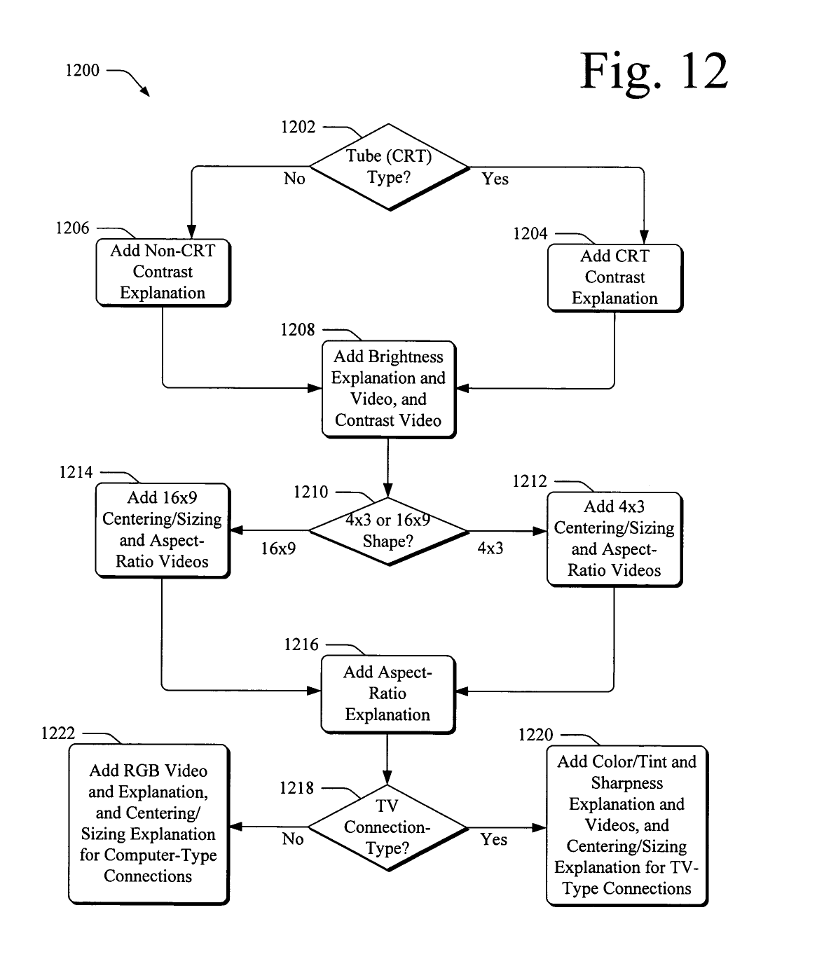

In one implementation, the system 300 tailors the instructions 328 by selecting from various modules of the instructions 328 to build a tailored list of the instructions 328 for the user's particular type of display. These modules of the instructions 328 can include various different types of the motion videos 330. An exemplary implementation of block 404 is shown in FIG. 12, which will be described below.

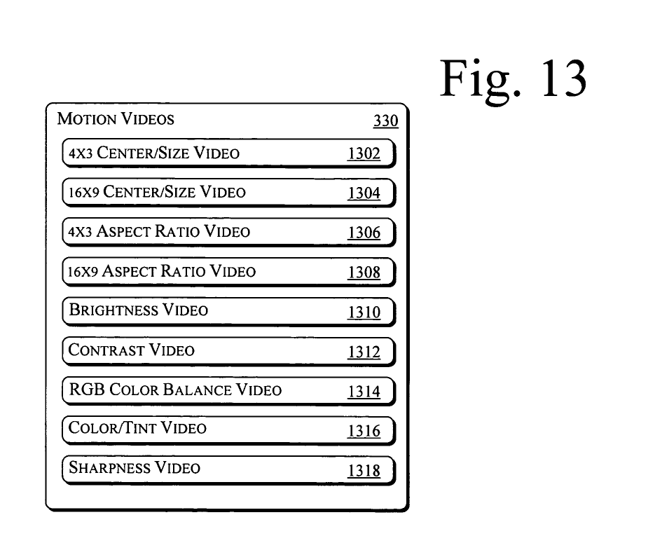

One example of the motion videos 330 is that of the standard-shape display-calibration video 200 shown in FIG. 2. In this example, the video 200 is selected by the system 300 to be presented as part of the instructions 328 because the user's display type is one having a standard shape (a 4×3 width-to-height ratio). Exemplary types of the motion videos 330 and their accompanying video explanations 332 will be set forth FIG. 13 and described in greater detail below.

At block 406, the system 300 presents the tailored instructions 328 to aid a user in calibrating the user's display. In doing so, the system 300 enables the user to more easily calibrate his or her display. The user does not need to relate a generic instruction (such as the grid and cross-hatch test screen 100 of FIG. 1) to his or her own type of display.

Determining a User's Display Type

FIG. 5 shows a process 500, which is an exemplary implementation of the block 402 of FIG. 4. This implementation sets forth one way in which the system 300 can determine the user's display's type and connection. Like the display type, the connection type can be useful in tailoring the instructions to aid a user in calibrating his or her display.

At block 502, the system 300 presents various display-type options, including tube (a traditional television/monitor; short for “cathode ray tube”), panel, rear projection, and forward-projection. The system 300 can do so through the user interface 324, including by displaying the display-type question menus 326. The system 300 can present these options with text, graphics, or both.

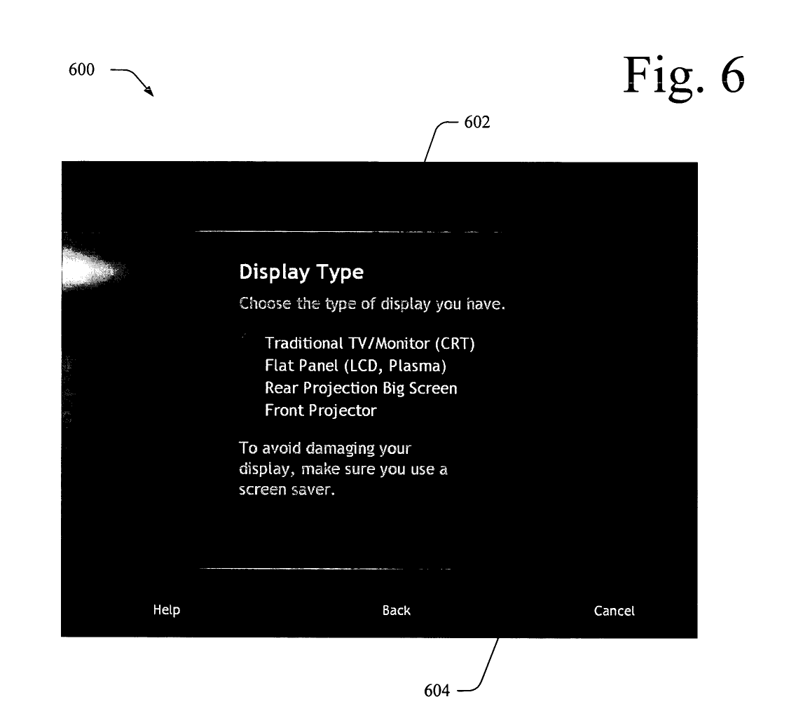

FIG. 6 sets forth a screen shot 600 of an example of the display-type question menus 326, here a general display-type selection menu 602. This general selection menu 602 sets forth display types from which a user can select. As shown in FIG. 6, the display-type selection menu 602 can include text describing each display type and graphics illustrating a display type. FIG. 6 also sets forth an example of a traditional/CRT graphic 604, which illustrates an appearance of many traditional/CRT monitors. Graphics used by the system 300 can include simple line drawings, pictures, icons, and the like.

This graphic 604, as well as others shown below, can help a user understand what type of display he or she has.

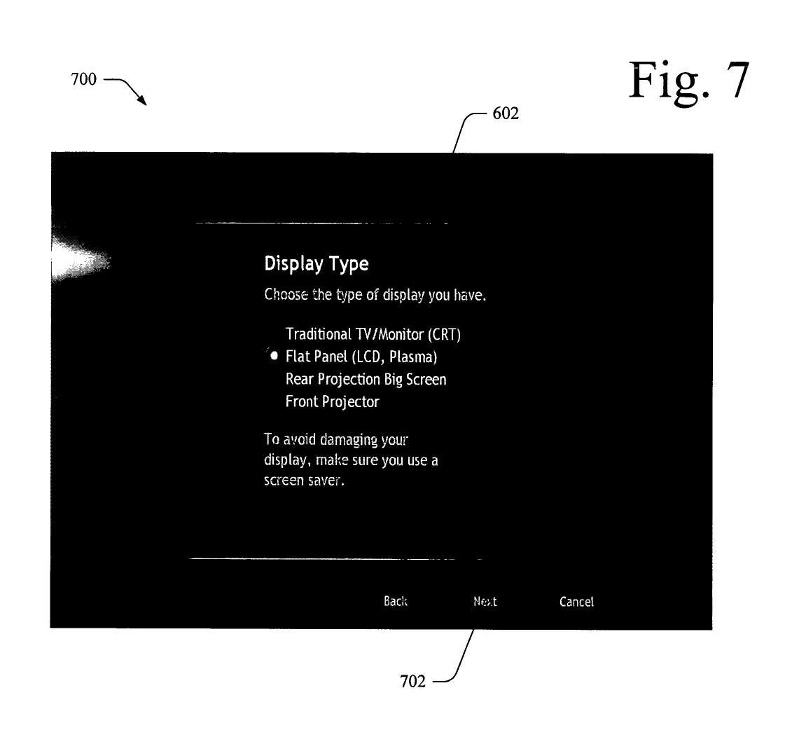

FIG. 7 sets forth a screen shot 700 of the general display-type selection menu 602 and an example of a flat-panel graphic 702. The graphic 702 illustrates an appearance of many flat panel displays.

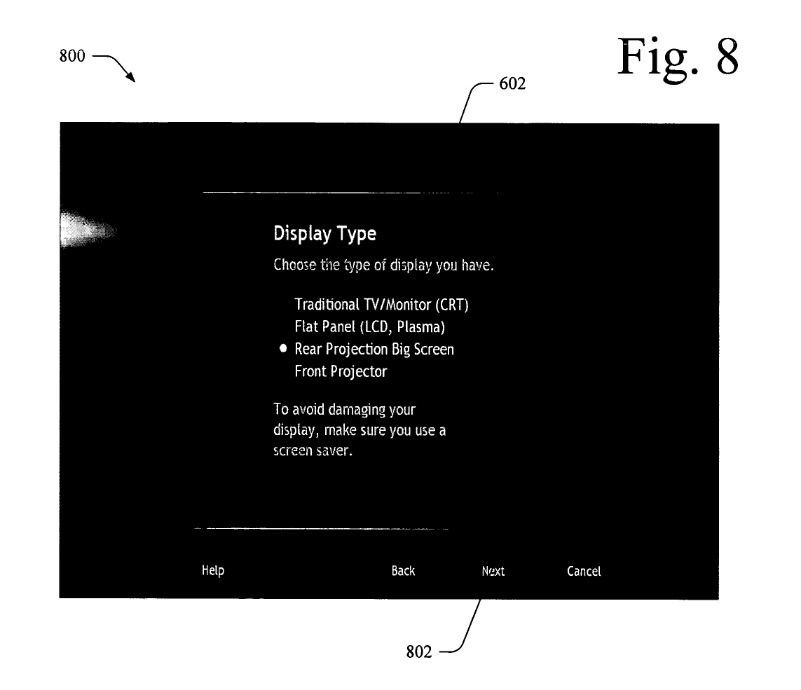

FIG. 8 sets forth a screen shot 800 of the general display-type selection menu 602 and an example of a rear-projection big screen graphic 802. The graphic 802 illustrates an appearance of many rear-projection big screen displays.

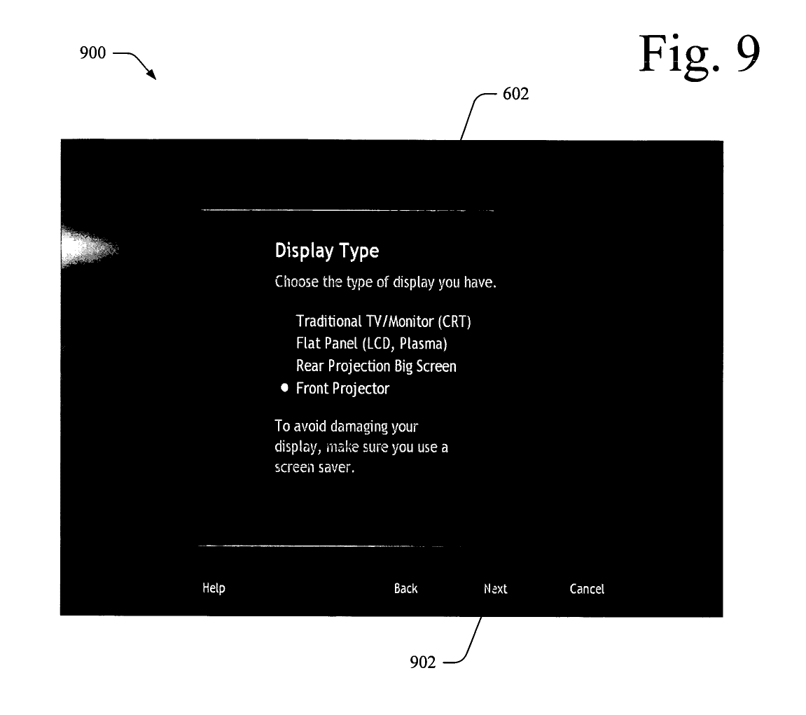

FIG. 9 sets forth a screen shot 900 of the general display-type selection menu 602 and an example of a front-projector graphic 902. The graphic 902 illustrates an appearance of many front-projector displays (without a projection screen).

In the implementations set forth in FIGS. 6, 7, 8, and 9, the system 300 presents a list of textual descriptions of display types and graphics illustrating each display type. In these implementations, the system 300 presents a graphic when a user hovers a selector (such as a mouse icon) over a related textual description. The system 300 can present graphics in other manners, such as by presenting all of the graphics 604, 702, 802, and 902 at once, by rotating through each graphic while indicating which textual description relates to the graphic currently shown, and the like. The system 300 can also present just the graphics 604, 702, 802, and 902 and enable selection of each display-type option by selecting (such as by clicking with the mouse 314 or highlighting and selecting with the remote control 310) on each graphic.

These are examples of how the system 300 can present display-type options. As part of doing so, the system 300 can also enable selection of each display-type option, such as by enabling a user to select an option by clicking on a button, on text, or on one of the graphics.

At block 504, the system 300 receives a selection of one of the general display types. It can receive the selection through the user interface 324 and the user input device 306.

Following block 504, the system 300, though blocks 506, 508, and 510 determines which submenu of the display-type question menus 326 is appropriate to display. Thus, certain selections from the general selection menu 602 invite or preclude other menus by which the system 300 determines the user's display type.

At block 506, if the selection is of the tube-type, the system 300 proceeds along the “Yes” path to block 514. If not, it proceeds along the “No” path to block 508.

At block 508, if the selection is of the panel-type, the system 300 proceeds along the “Yes” path to block 514. If not, it proceeds along the “No” path to block 510.

At block 510, if the selection is of the rear-projection-type, the system 300 proceeds along the “Yes” path to block 516. If not, it proceeds along the “No” path to block 512.

At block 512, the selection is of the front-projector-type, so the system 300 proceeds to block 518.

At block 514, the system 300 presents shape options to determine the shape of the user's display.

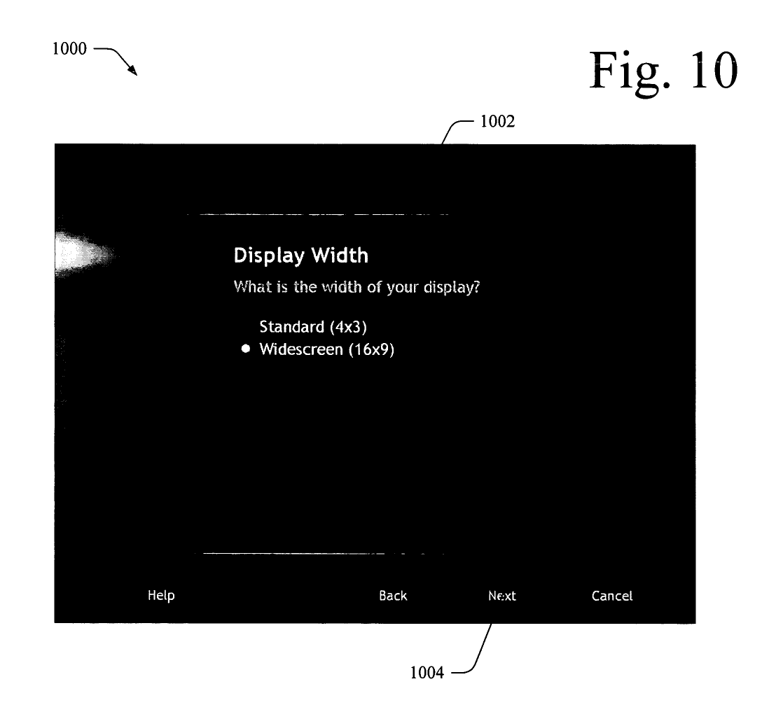

FIG. 10 sets forth a screen shot 1000 of an example of the display-type question menus 326, here a shape menu 1002. This shape menu 1002 presents two shape options to a user, a 4×3 shape (called “standard”) and a 16×9 shape (called “widescreen”). As shown in FIG. 10, the shape menu 1002 can include text describing each shape (or “aspect ratio”) and graphics illustrating the shape. FIG. 10 sets forth an example of a widescreen graphic 1004, which illustrates a shape of widescreen displays. The system 300 can also display other graphics illustrating other shapes, such as a standard-shaped display (not shown). The user can select one of these shapes, by which the system 300 can tailor the instructions 328 to aid the user in calibrating his or her display.

At block 516, the system 300 presents a cathode-ray-tube (CRT) options to determine whether or not the user's rear-projection-type display is of the CRT or the non-CRT type.

At block 518, the system 300 presents a one/three light menu to determine whether or not the user's front-projection display is of the one-light or the three-light type.

After blocks 516 and 518 the system 300 receives the user's selection of the various options at block 520. After block 520, the system 300 proceeds to block 514, described above.

At block 522, the system 300 receives a selection of the shape of the user's display.

At this point, the system 300 has determined the type of display in use by the user. Thus, through this exemplary process for block 402 of FIG. 4, the system 300 can determine that the user's type of display is one of the following display types: a 4×3 shape CRT; a 4×3 shape panel; a 4×3 shape, non-CRT rear-projection; a 4×3 shape, CRT rear-projection; a 4×3 shape, one-light front-projection; a 4×3 shape, three-light front projection; a 16×9 shape CRT; a 16×9 shape panel; a 16×9 shape, non-CRT rear-projection; a 16×9 shape, CRT rear-projection; a 16×9 shape, one-light front-projection; or a 16×9 shape, three-light front-projection.

The system 300 can stop here or continue to gather information from the user, such as a connection type for the user's display.

At block 524, the system 300 presents television and computer connection types. Television connection types can include an S-video cable, a coaxial cable, a composite cable, and the like. Computer connection types can include those for DVI and VGA, as well as many-pronged connectors, universal connectors, and wireless connectors, to name a few.

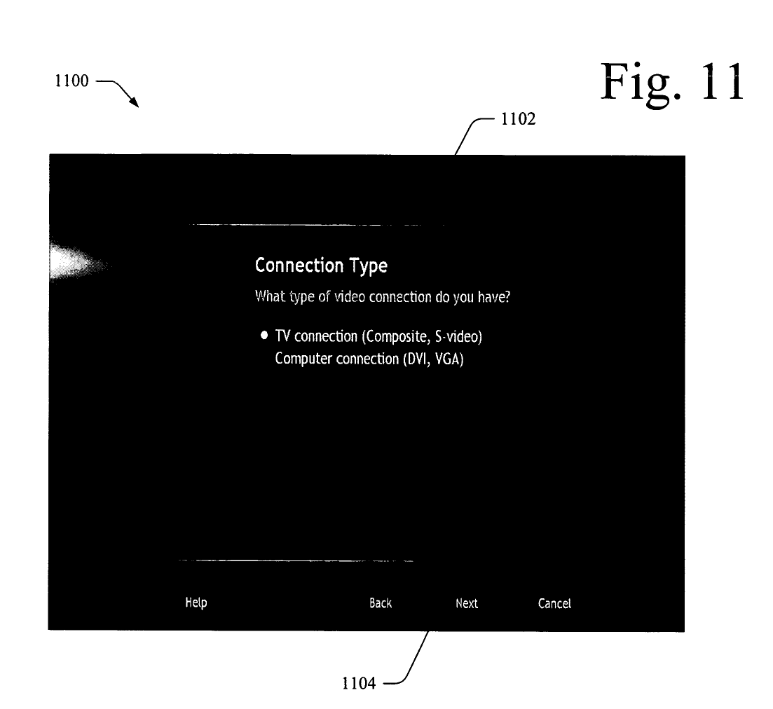

FIG. 11 sets forth a screen shot 1100 of an example of the display-type question menus 326, here a connection-type menu 1102. This connection-type menu 1102 presents two connection-type options to a user, a television connection-type and a computer connection-type. As shown in FIG. 11, the connection-type menu 1102 can include text describing each connection type and graphics illustrating the connection types. FIG. 11 sets forth an example of a television connection-type graphic 1104, which illustrates three connections that are television connection types, and a computer connection-type graphic 1106, which illustrates two connections that are computer connection types. The user can select one of these connection-type options, by which the system 300 can tailor the instructions 328 to aid the user in calibrating his or her display.

At block 526 the system 300 receives a selection of a TV or computer type of connection.

At this further point, the system 300 has determined not only the display type, such as set forth above, but also the display's connection type.

The system 300 (following block 404 of FIG. 4) then proceeds to tailor the instructions 328 to the type of display (and in some cases the type of connection and/or shape) selected by the user. The system 300 is not limited to the above-listed types of displays or connection types. Rather, these display and connection types are one implementation of display and connection types for which the system 300 can tailor instructions.

Tailoring the Instructions

FIG. 12 shows a process 1200, which is an exemplary implementation of the block 404 of FIG. 4. This implementation is one way in which the system 300 can tailor the instructions 328 to the user's type of display and connection. In this implementation, the system 300 tailors the instructions 328 by selecting from the motion videos 330 shown in FIG. 13 below. The system 300 can also tailor the instructions 328 by selecting appropriate explanations from the video explanations 332 showing how to use the motion videos 330 based on the display's type and connection.

Because the motion videos 330 are referred to as part of FIG. 12, a brief summary of FIG. 13 will be given here. A more detailed description of FIG. 13 and the motion videos 330 will be given after the description of FIG. 12.

FIG. 13 shows one implementation of the motion videos 330. In this implementation, the motion videos 330 include nine motion videos. Each of these motion videos are designed to aid a user in calibrating one or more parameters of a display. These videos include a 4×3 center/size video 1302, a 16×9 center/size video 1304, a 4×3 aspect-ratio video 1306, a 16×9 aspect-ratio video 1308, a brightness video 1310, a contrast video 1312, an RGB (Red Green Blue) balance video 1314, a color/tint video 1316, and a sharpness video 1318. The video 200, shown in part in FIG. 2, is an example of the 4×3 center/size video 1302.

Using these videos of the motion videos 330, the system 300 can tailor the instructions 328 to a user's type of display and connection by selecting which of the motion videos 330 to present to the user.

At block 1202, the system 300 determines if the display is of the tube type. If the user's display type is a tube (CRT) display, the system 300 proceeds along the “Yes” path to block 1204. If not, the system 300 proceeds along the “No” path to block 1206.

At block 1204, the system 300 tailors the instructions 328 by adding an explanation (from the video explanations 332) for the contrast video 1312 that is designed for use with a CRT-type display.

At block 1206, the system 300 tailors the instructions 328 by adding an explanation (from the video explanations 332) for the contrast video 1312 that is designed for use with a Non-CRT-type display.

At block 1208, the system 300 tailors the instructions 328 by adding the brightness video 1310 and an appropriate explanation from the video explanations 332, and the contrast video 1312.

At block 1210, the system 300 determines whether or not the user's display has a 4×3 or a 16×9 shape. If the user's display is 4×3 (also called “4:3”) the system 300 proceeds along the “4×3” path to block 1212. If the user's display is 16×9 (also called “16:9”) the system 300 proceeds along the “16×9” path to block 1214.

At these blocks 1212 and 1214, the system 300 tailors the instructions 328 by adding either the 16×9 center/size video 1304 and the 16×9 aspect-ratio video 1308 or the 4×3 center/size video 1302 and the 4×3 aspect-ratio video 1306.

At block 1216, the system 300 adds an explanation from the video explanations 332 showing a user how to use the aspect-ratio video 1306 or 1308.

At block 1218, the system 300 determines if the display has a TV type of connection or not. If the user's connection type is TV, the system 300 proceeds along the “Yes” path to block 1220. If not, the system 300 proceeds along the “No” path to block 1222.

At block 1220, the system 300 tailors the instructions 328 by adding the color/tint video 1316 and the sharpness video 1318 and appropriate explanations from the video explanations 332 showing how to use them. The system 300 also adds an explanation from the video explanations 332 showing how to use the centering/sizing video 1302 or 1304 for a display having a TV connection type.

At block 1222, the system 300 tailors the instructions 328 by adding the RGB balance video 1314 and an appropriate explanation from the video explanations 332 showing how to use it. The system 300 also adds an explanation from the video explanations 332 showing how to use the centering/sizing video 1302 or 1304 for a display having a computer connection type.

Through this process 1200, the system 300 can tailor the instructions 328 to the user's type of display and connection. This implementation of block 404 is shown to aid the reader in understanding one way in which the system 404 can tailor the instructions 328 to a user's type of display and connection and is not intended to be limiting on the how the system 300 can implement block 404.

Exemplary Motion Videos

As set forth in FIG. 3, the instructions 328 can include the motion videos 330 and their video explanations 332. These motion videos 330 can include multiple different videos, each of which is designed to help a user calibrate his or her display easily and intuitively.

As mentioned above, FIG. 13 shows one implementation of the motion videos 330. FIG. 13 includes nine motion videos, each designed to aid a user in calibrating a parameter of his or her display.

As will be shown in greater detail below, each of these motion videos are carefully designed and photo-realistic, thereby enabling a user to more easily and intuitively calibrate his or her display. They include real objects that many users are familiar with, which makes the motion videos easier for users to use and understand than many currently used technical and/or computer-generated test screens.

Also, because the motion videos have moving, photo-realistic objects, users can more easily calibrate their displays to use them for viewing video programs and movies. This is because moving, photo-realistic objects in the motion videos are easier for users to relate to viewing video programs and movies than still test screens.

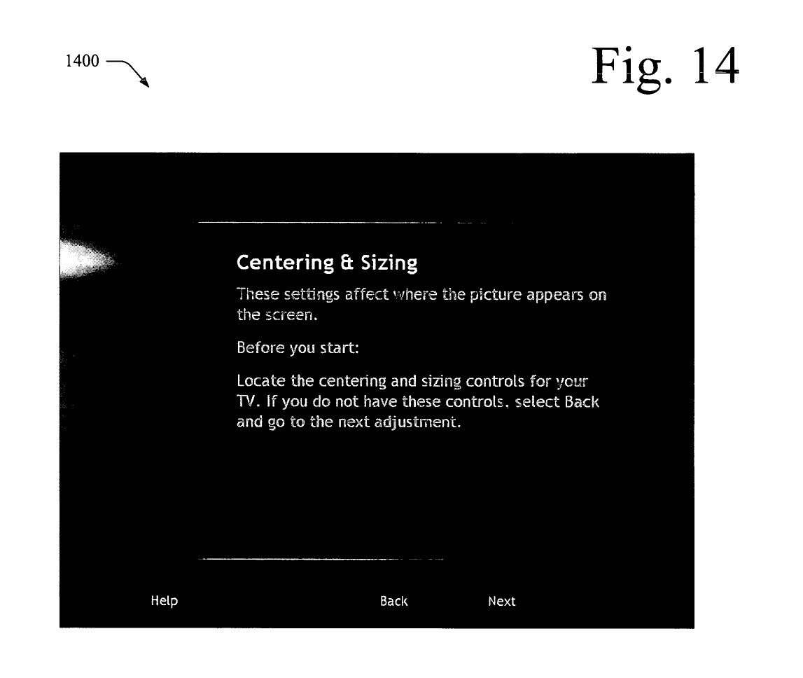

FIGS. 14 to 35 set forth screen shots of exemplary implementations of these motion videos 330 and their video explanations 332. These screen shots are shown in black-and-white, though the motions videos 330 and the explanations 332 are in color. The screen shots also represent snapshots of these exemplary motion videos 330. The exemplary motion videos 330 themselves are in motion, though this can not practically be shown using figures.

The 4×3 Center/Size Video 1302 and the 16×9 Center/Size Video 1304

The 4×3 center/size video 1302 and the 16×9 center/size video 1304 are designed to aid a user in centering and sizing media on his or her display. The 4×3 center/size video 1302 is designed for use with a 4×3-shaped display and a CRT or non-CRT type of display. The 16×9 center/size video 1304 is designed for use with a 16×9-shaped display and a CRT or non-CRT type of display. These videos 1302 and 1304 include photo-realistic objects, which can be moving or still.

The 4×3 center/size video's 1302 and the 16×9 center/size video's 1304 photo-realistic object(s) aid a user by being hyper-sensitive to calibration changes that are outside of an optimum range.

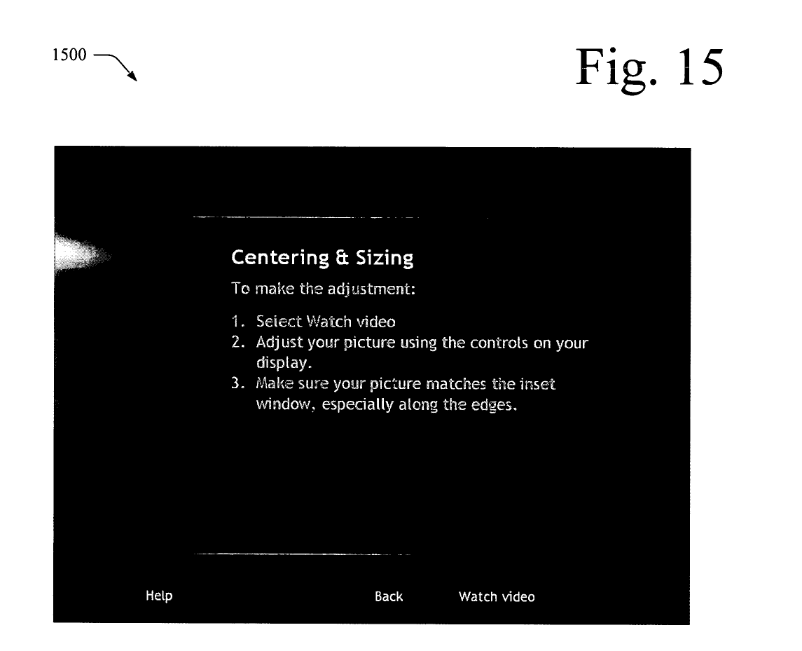

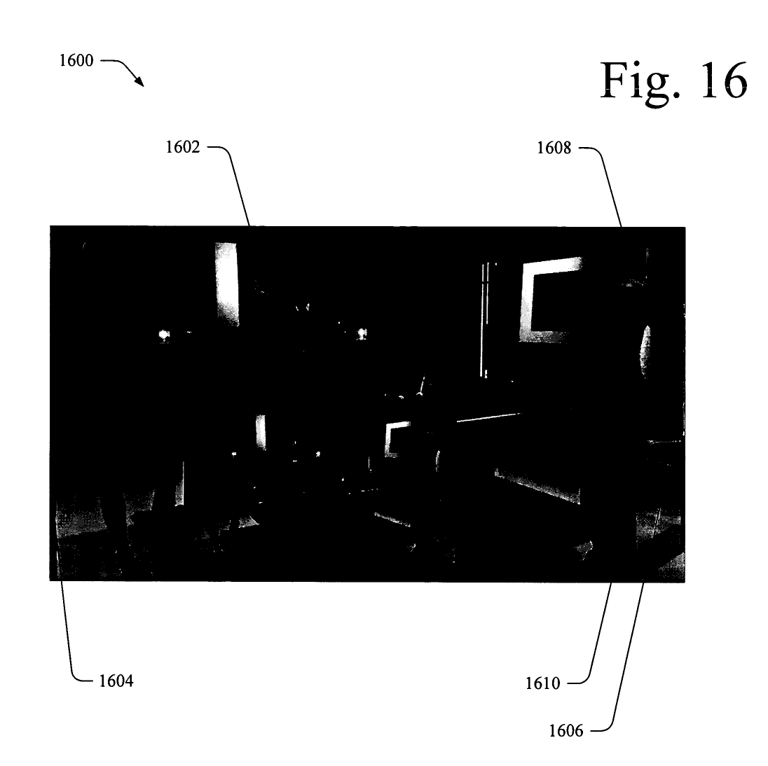

Exemplary implementations of the 4×3 center/size video 1302 and the 16×9 center/size video 1304 set forth photo-realistic objects that are hyper-sensitive to calibration changes. These exemplary implementations are partially shown in FIGS. 2 and 16 and explained in FIGS. 14 and 15.

FIGS. 14 and 15 set forth center/size screen shots 1400 and 1500 of an exemplary implementation of the video explanations 332. This implementation of the video explanations 332 explains how to use the 4×3 center/size video 1302 and the 16×9 center/size video 1304. These videos are structured differently, as will become apparent, because each is designed for use with a particular shape of a display.

FIG. 2 shows a screen shot of the video 200, which is an exemplary implementation of the 4×3 center/size video 1302. The 4×3 center/size video 1302 is designed for use with a display having a 4×3 (standard) shape.

FIG. 16 sets forth a 16×9 center/size screen shot 1600 of an exemplary implementation of the 16×9 center/size video 1304 of FIG. 13. The 16×9 center/size video 1304 is designed for use with a display that has a 16×9 shape.

These videos 1302 and 1304 help a user calibrate his display in an easy-to-use and intuitive way. They do so in part because they include real objects.

These implementations shown in FIGS. 2 and 16 of the videos 1302 and 1304 help the user by showing the user a small video showing how the display should look when the centering and sizing parameters are optimized. The exemplary 4×3 center/size video 1302 shown in FIG. 2 includes the small 4×3 video 210 within the larger part of the video 1302. The exemplary 16×9 center/size video 1304 shown in FIG. 16 includes a small 16×9 video 1602 within a larger part of the video 1304. These small videos 210 and 1602 within the larger videos are a clear and easy-to-understand way to show how the larger video should look when the user's display's centering and sizing parameters are optimal.

Further, the videos 1302 and 1304 help the user calibrate his display's centering and sizing parameters by being hyper-sensitive to calibration changes.

The exemplary 16×9 center/size video 1304 of FIG. 16, for instance, has certain unmoving (or only slightly moving) objects to aid the user. Both of the pool cues, a left pool cue 1604 and a right pool cue 1606 are partially shown and very thin. This aids the user because if the user calibrates the display to show the exemplary 16×9 center/size video 1304 slightly too large, the pool cues will disappear, even with a very slight calibration error. Likewise, the left pool cue 1604 will disappear if the exemplary 16×9 center/size video 1304 is only very slightly moved too far left by the user's centering calibration. Similarly, the right pool cue 1606 will disappear if the exemplary 16×9 center/size video 1304 is only very slightly moved too far right. Also, if the user calibrates the display only slightly too far up or down, a right woman's head 1608 or a right woman's heel 1610 will be cut off.

Thus, the 4×3 center/size video 1302 and the 16×9 center/size video 1304 are carefully tailored to aid the user in optimizing his display's centering and sizing parameters, while also being easy and intuitive to use.

The 4×3 Aspect-Ratio Video 1306 and the 16×9 Aspect-Ratio Video 1308

The 4×3 aspect-ratio video 1306 and the 16×9 aspect-ratio video 1308 are designed to aid a user in calibrating an aspect ratio of his or her display. The 4×3 aspect-ratio video 1306 is designed for use with a 4×3-shaped display. The 16×9 aspect-ratio video 1308 is designed for use with a 16×9-shaped display. These videos 1306 and 1308 include a photo-realistic object, which can be moving or still.

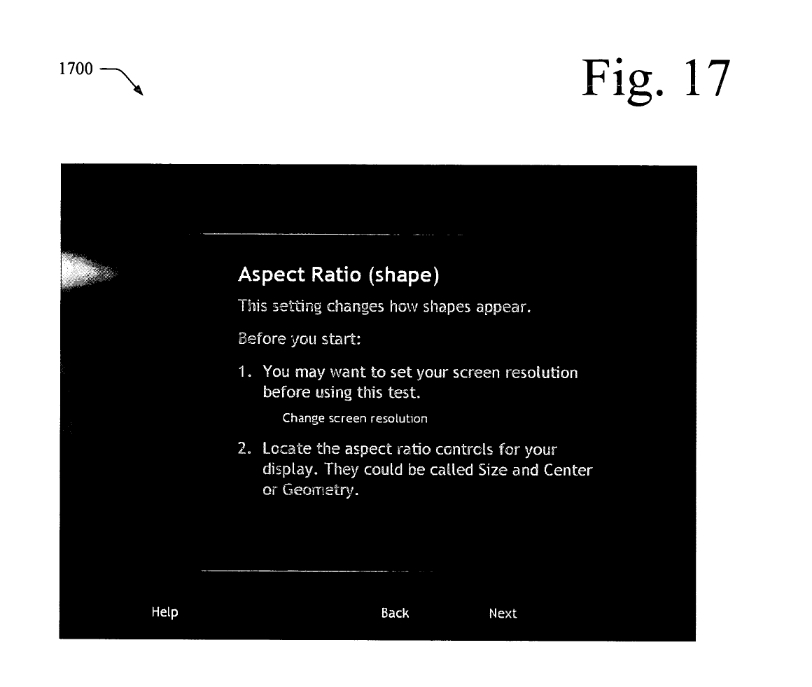

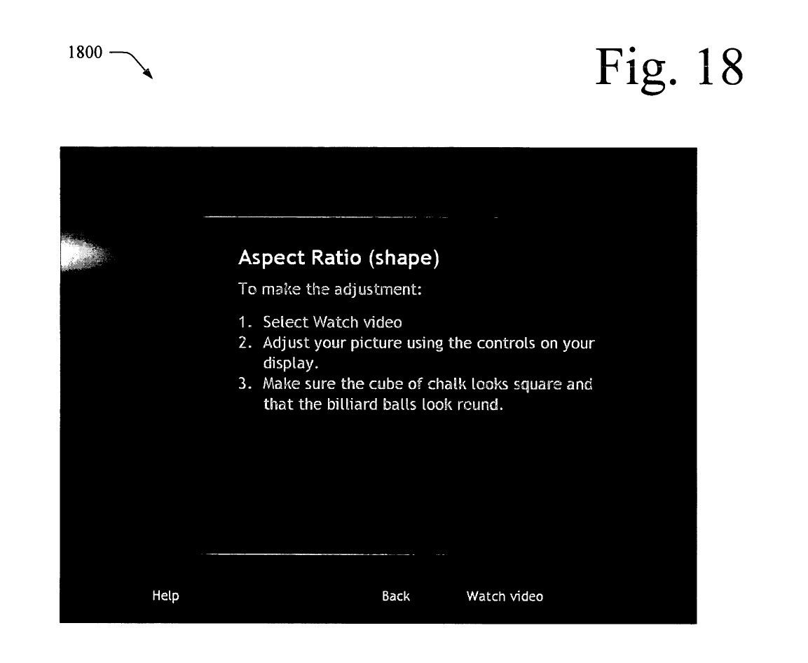

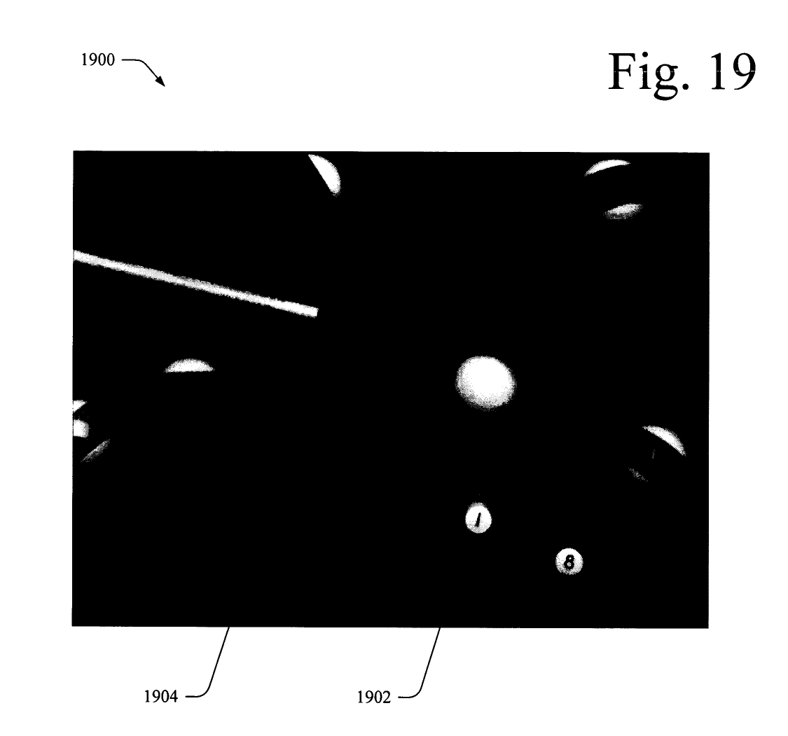

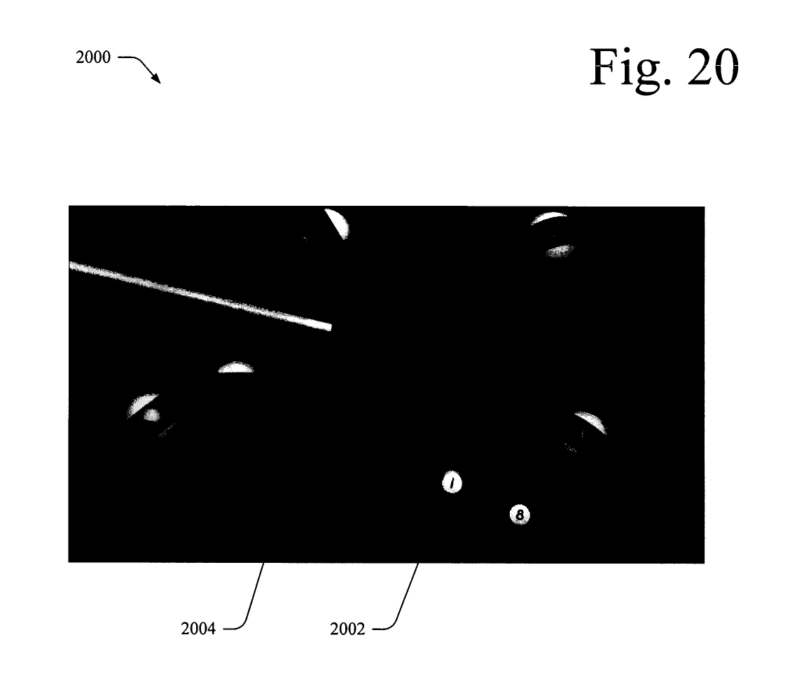

The 4×3 aspect-ratio video's 1306 and the 16×9 aspect-ratio video's 1308 photo-realistic object or objects aid a user by appearing unrealistic when a display is calibrated outside of an optimum range. Exemplary implementations of these videos 1306 and 1308 are partially shown in FIGS. 19 and 20 and explained in FIGS. 17 and 18.

FIGS. 17 and 18 set forth aspect-ratio explanation screen shots 1700 and 1800 of an exemplary implementation of the video explanations 332. This implementation of the video explanations 332 explains how to use the 4×3 aspect-ratio video 1306 and the 16×9 aspect-ratio video 1308. These videos are structured differently, as will become apparent, because each is designed for use with a particular shape of a display.

FIG. 19 sets forth a 4×3 aspect-ratio screen shot 1900 of an exemplary implementation of the 4×3 aspect-ratio video 1306 of FIG. 13. The 4×3 aspect-ratio video 1306 is designed for use with a display that has a 4×3 shape.

FIG. 20 sets forth a 16×9 aspect-ratio screen shot 2000 of an exemplary implementation of the 16×9 aspect-ratio video 1308 of FIG. 13. The 16×9 aspect-ratio video 1308 is designed for use with a display that has a 16×9 shape.

These videos 1306 and 1308 help a user calibrate his display in an easy-to-use and intuitive way. They do so in part because they are not intimidating or hard to understand; they show real objects.

These implementations shown in FIGS. 19 and 20 of the videos 1306 and 1308 help the user calibrate his display's aspect-ratio parameter by being hyper-sensitive to calibration changes. Pool balls, such as a 4×3 ball 1902 and 16×9 ball 2002 are round. These round balls are designed to show an accurate and highly round object, so that with a small calibration change a user will notice that the ball does not look quite round. Likewise, a 4×3 chalk 1904 and a 16×9 chalk 2004 are designed to show an accurate and highly square object, so that with a small calibration change a user will notice that the chalk does not look quite square. These objects are real-world and known to an average user. Because of users' familiarity with these real objects, many users can easily understand what calibration changes are needed to set the aspect ratio parameter on their display within an optimum range.

Thus, the aspect-ratio videos 1306 and 1308 are carefully tailored to aid the user in optimizing his or her display's aspect-ratio parameter, while also being easy and intuitive to use.

The Brightness Video 1310

The brightness video 1310 is designed to aid a user in optimizing a brightness parameter for his or her display. The brightness video 1310 can be used with a 4×3- or 16×9-shaped display, and a CRT or non-CRT type of display. The brightness video 1310 can use still or moving photo-realistic objects.

The brightness video's 1310 photo-realistic object(s) aids a user by having a brightness such that adjusting a brightness calibration of a user's display outside of an optimum range causes the object to appear unrealistic to the user.

In another implementation, the brightness video's 1310 photo-realistic object aids a user by being hyper-sensitive to adjustments in the brightness calibration of the user's display.

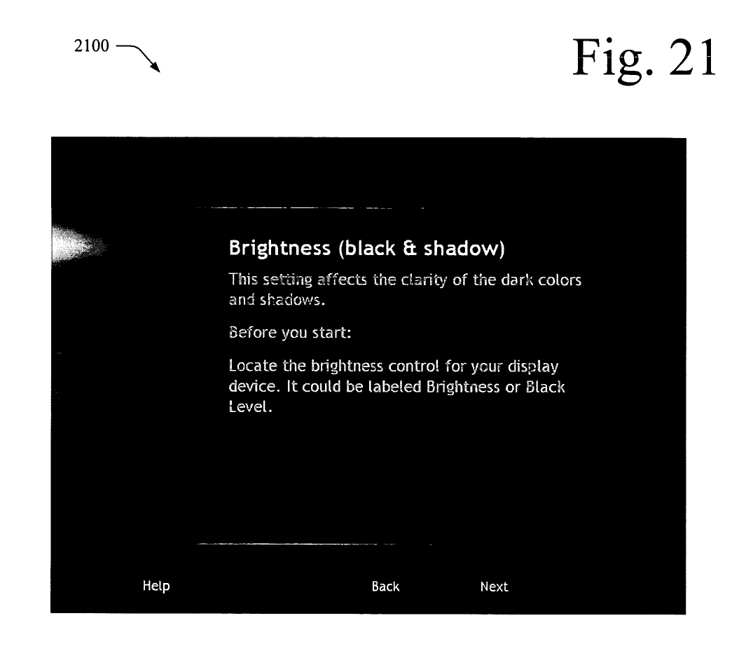

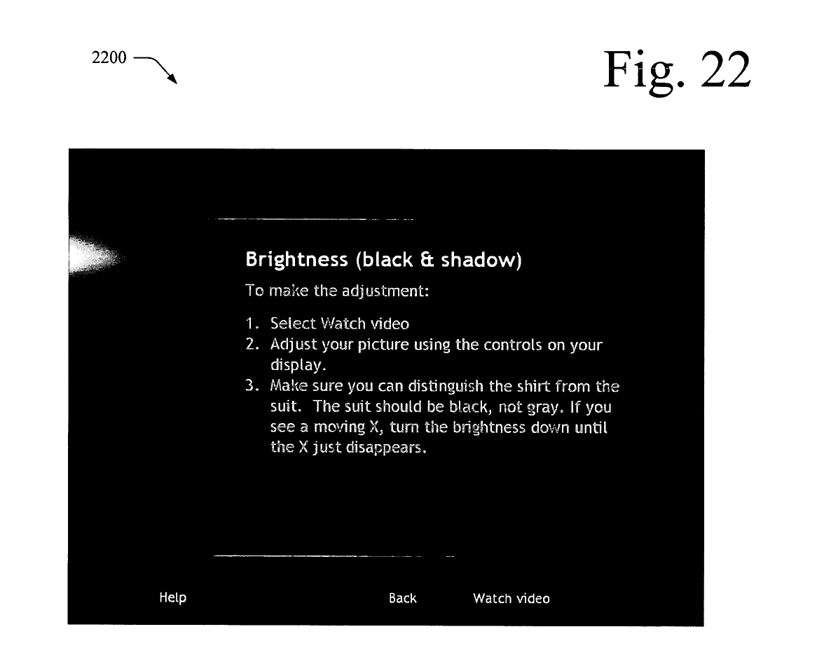

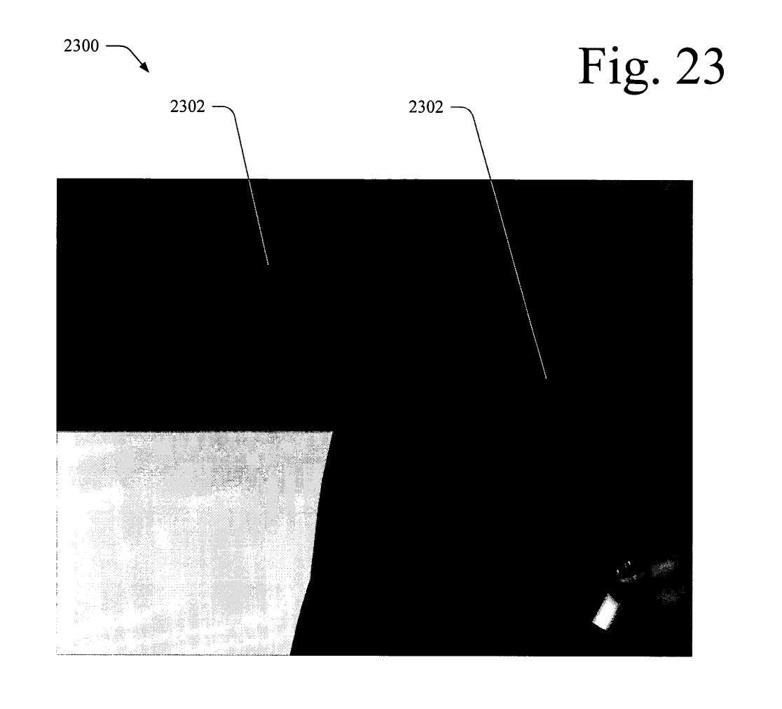

An example of a photo-realistic object that appears unrealistic even for small brightness changes is shown in an exemplary implementation of the brightness video 1310. This exemplary implementation is partially shown in FIG. 23 and explained in FIGS. 21 and 22.

FIGS. 21 and 22 set forth brightness-explanation screen shots 2100 and 2200 and show an exemplary implementation of the video explanations 332. This implementation of the video explanations 332 explains how to use the exemplary implementation of the brightness video 1310 shown in FIG. 23.

FIG. 23 sets forth a brightness-video screen shot 2300 of the exemplary implementation of the brightness video 1310 of FIG. 13. Here a photo-realistic object, a man's suit and shirt 2302, appears unrealistic if a display's brightness is turned too low, even if only slightly. When turned lower than an optimum range, the shirt, which should appear dark gray, blends into the suit, which should appear black.

Similarly, another photo-realistic object, a black background 1304, appears unrealistic if a display's brightness is turned too high, even if only slightly. When the brightness parameter is calibrated above an optimum range, the black background 2304, which should appear solid, appears to have a moving X within it.

This implementation of the brightness video 1310 simulates aspects of a testing screen called PLUGE (Picture Line-Up GEneration), though with easy-to-use and intuitive photo-realistic objects.

The Contrast Video 1312

The contrast video 1312 is designed to aid a user in optimizing a contrast parameter for his or her display. The contrast video 1312 can be used with a 4×3- or 16×9-shaped display, and a CRT or non-CRT type of display (though the explanation of it can be different based on whether or not the display is CRT or not).

The contrast video's 1312 photo-realistic object(s) aids a user by having a structure such that adjusting a contrast calibration of a user's display outside of an optimum range causes the object to appear unrealistic to the user.

In another implementation, the contrast video's 1312 photo-realistic object aids a user by being hyper-sensitive to adjustments in the contrast calibration of the user's display.

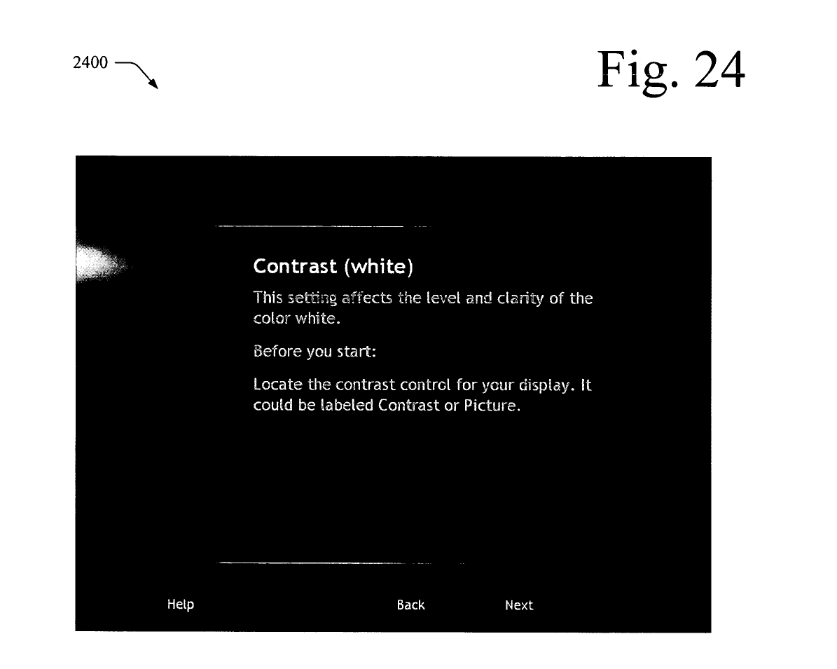

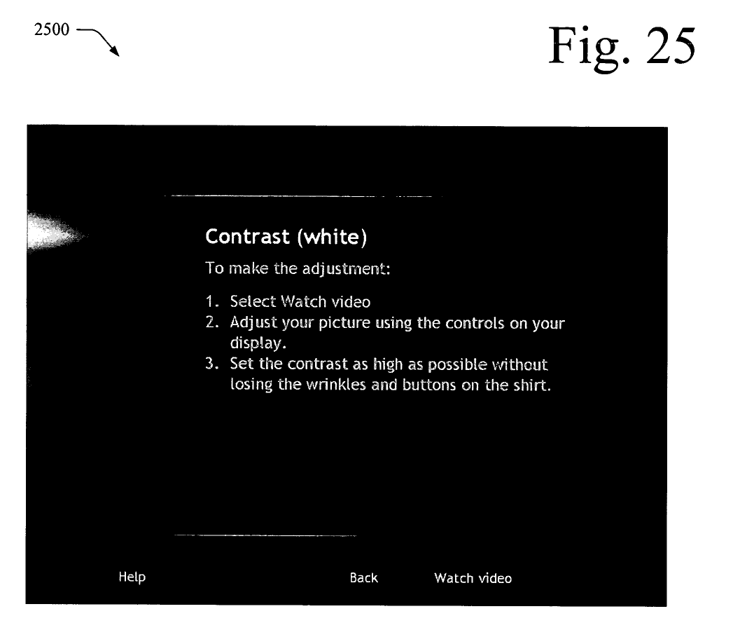

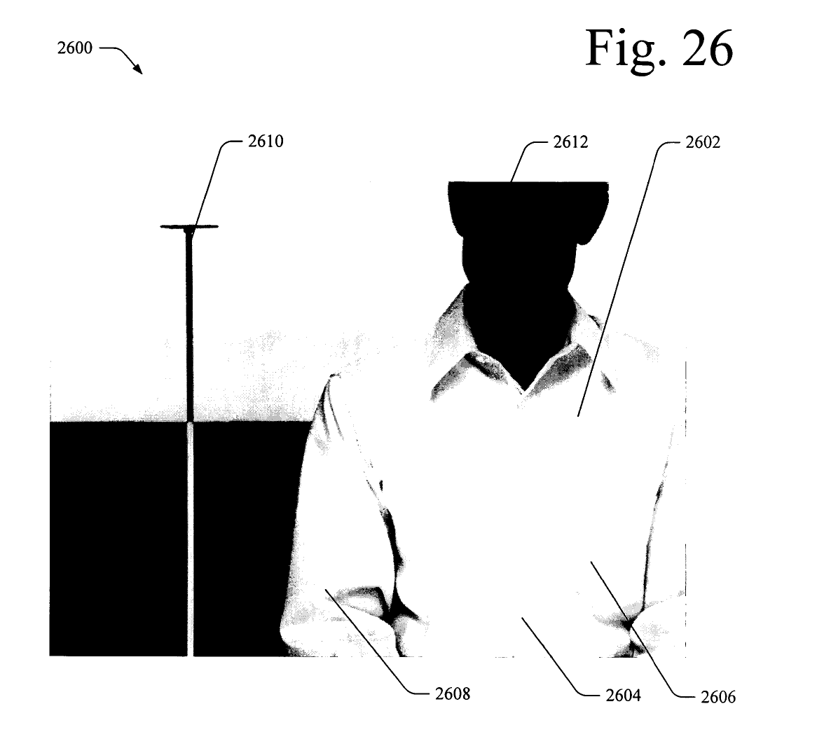

An example of a photo-realistic object that appears unrealistic even for small contrast changes is shown in an exemplary implementation of the contrast video 1312. This exemplary implementation is partially shown in FIG. 26 and explained (for non-CRT displays) in FIGS. 24 and 25.

FIGS. 24 and 25 set forth contrast-explanation screen shots 2400 and 2500 and show an exemplary implementation of the video explanations 332. The screen shot 2500 is designed for use with a display that is not a CRT. Thus, the screen shot 2500 explains how to use the exemplary implementation of the contrast video 1312 shown in FIG. 26 when the display is not a CRT. For CRT-type displays, the video explanations 332 used can explain a warping aspect of the implementation shown in FIG. 26, which will be described below.

FIG. 26 sets forth a contrast-video screen shot 2600 of the exemplary implementation of the contrast video 1312 of FIG. 13. Here a photo-realistic object, a man's shirt 2602, appears unrealistic if a display's contrast is adjusted outside of an optimum range. The man's shirt 2602 includes three areas that are hyper-sensitive to contrast changes and look correct when the contrast is within an optimum range. These areas are buttons 2604, a texture 2606, and creases 2608 on the shirt 2602.

For a non-CRT-type display, when the contrast is turned slightly too high, the texture 2606 disappears, when moderately too high, the buttons 2604 also disappear, and when much too high also the creases 2608 in the shirt 2602 disappear.

For a CRT-type display, when the contrast is turned slightly too high a black and white pool cue 2610 will bend or warp.

For either type of display, when the contrast is turned too low, the white background and the white shirt will appear unrealistic by looking dirty or gray. Also, when the contrast is turned too low the shirt 2602 and the man's face 2612 will look unrealistic.

The RGB Color Balance Video 1314

The RGB color balance video 1314 is designed to aid a user in optimizing a color balance parameter for his or her display. The RGB color balance video 1314 can be used with a 4×3- or 16×9-shaped display and a CRT- or non-CRT type of display that has a computer or other non-TV connection type.

The RBG color balance video's 1314 object(s) aids a user by having a structure such that adjusting an RGB (Red Green Blue) color balance parameter of a user's display outside of an optimum range causes the object to appear unrealistic to the user.

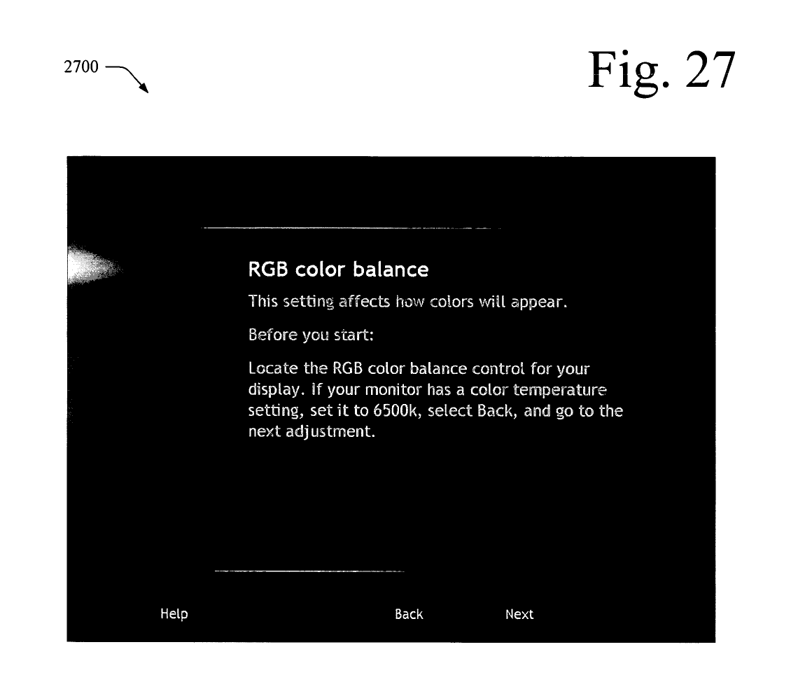

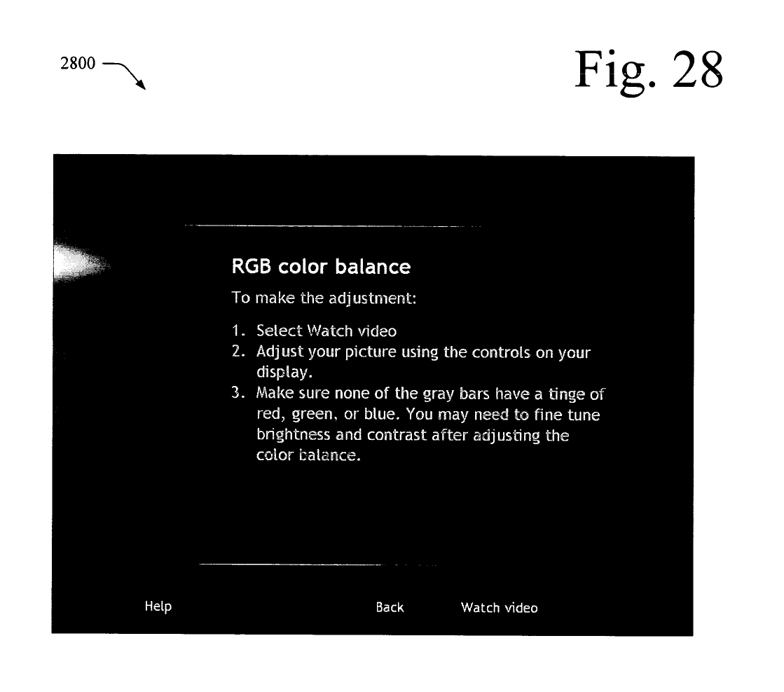

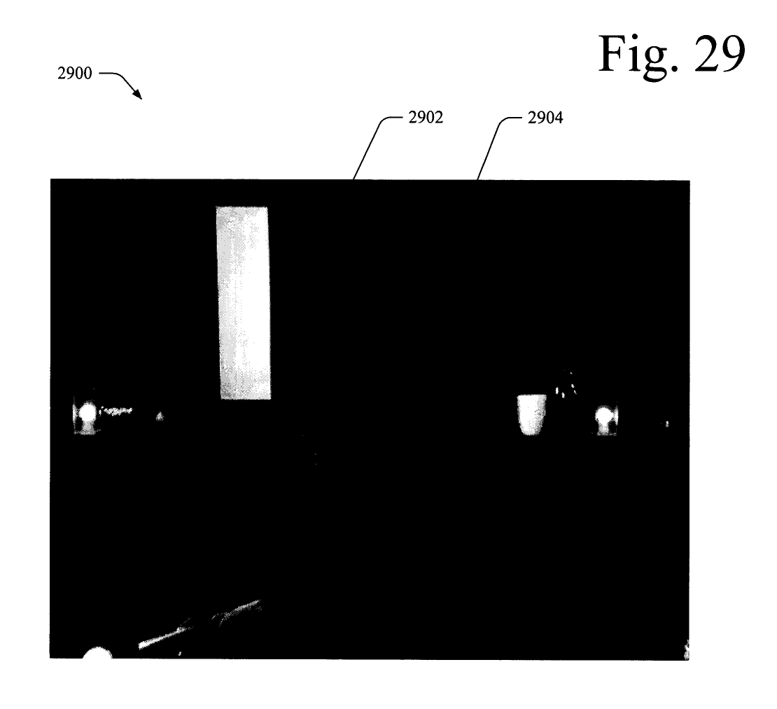

An example of an object that appears unrealistic outside of an optimum color balance range is shown in an exemplary implementation of the RGB color balance video 1314. This exemplary implementation is partially shown in FIG. 29 and explained in FIGS. 27 and 28.

FIGS. 27 and 28 set forth color/balance-explanation screen shots 2700 and 2800 and show an exemplary implementation of the video explanations 332. This implementation of the video explanations 332 explains how to use the exemplary implementation of the RGB color balance video 1314 shown in FIG. 29.

FIG. 29 sets forth an RGB color balance screen shot 2900 of the exemplary implementation of the RGB color balance video 1314 of FIG. 13. Here a black-and-white object, a gray bar painting 2902, appears less realistic if a display's color balance contrast is adjusted outside of an optimum range. The gray bar painting 2902 is designed to become reddish, greenish, or bluish if the color balance is set outside of an optimum range.

This exemplary implementation shown in FIG. 29 also has a color, photo-realistic object, a pool player 2904. The pool player 2904 gives the user a real-life, photo-realistic color object that is also affected by changes to the color balance parameter. This object helps the user relate changes to the color balance parameter to a real-life object, which makes adjusting the parameter easier and more intuitive for the user.

The Color/Tint Video 1316

The color/tint video 1316 is designed to aid a user in optimizing a color/tint parameter for his or her display. The color/tint video 1316 can be used with a 4×3- or 16×9-shaped display and a CRT- or non-CRT-type display that has a TV connection type.

The color/tint video's 1316 photo-realistic object aids a user by having a color (sometimes called a “saturation”) and tint (also called a “hue”) such that adjusting a color/tint calibration of a user's display outside of an optimum range causes the object to appear unrealistic to the user. In one implementation, the color/tint video's 1316 photo-realistic object appears unrealistic to unaided eyes of a user, thereby not requiring the user to use special glasses or other viewing aids.

In another implementation, the color/tint video's 1316 photo-realistic object aids a user by being hyper-sensitive to adjustments in the color/tint calibration of the user's display.

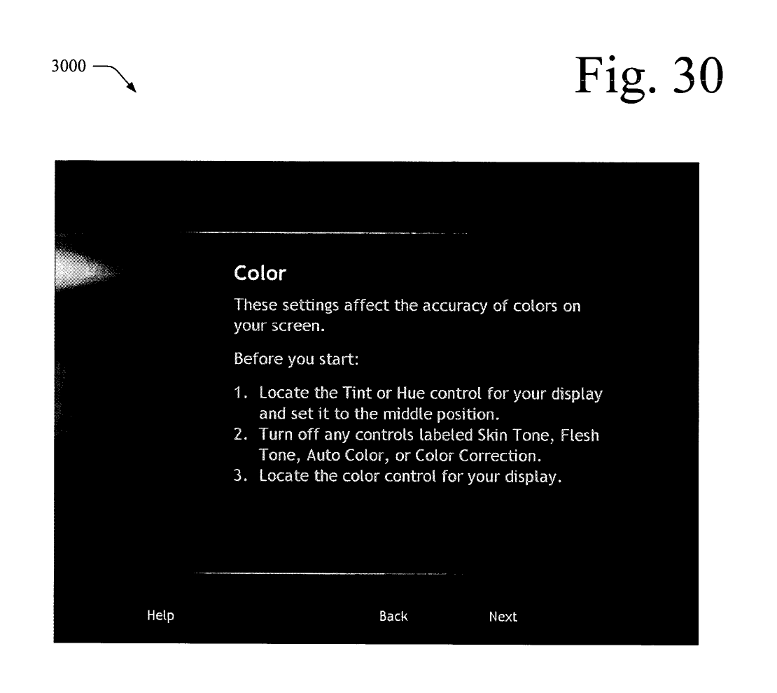

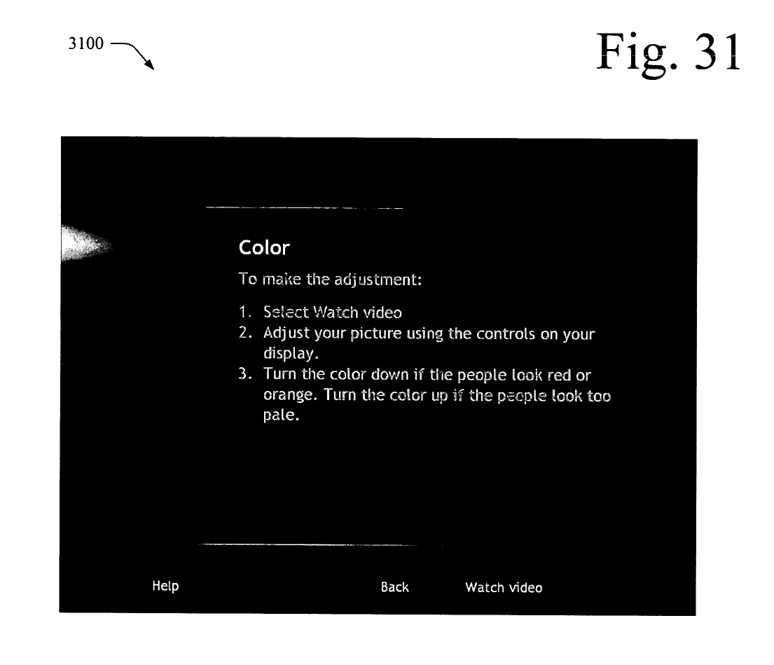

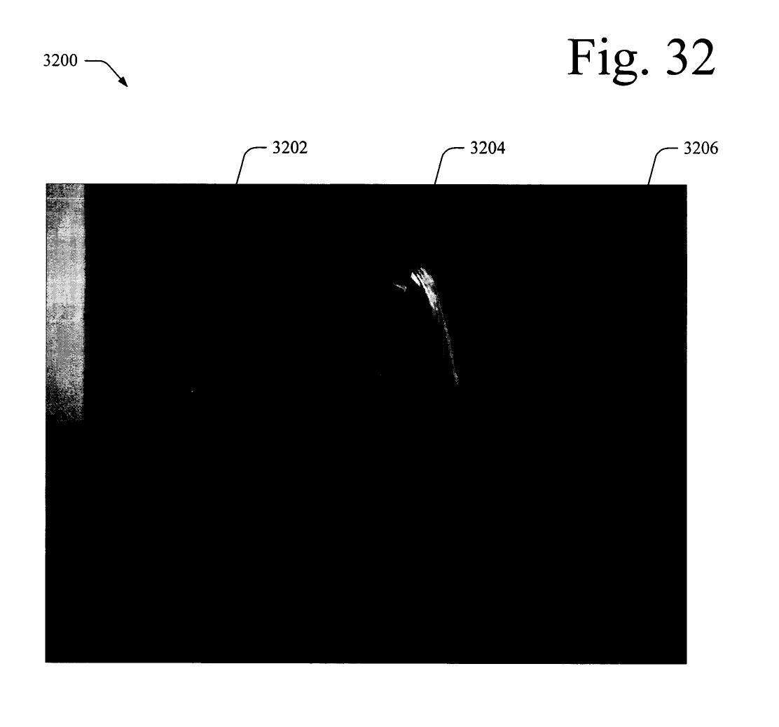

An example of a photo-realistic object that appears unrealistic even for small color/tint changes is shown in an exemplary implementation of the color/tint video 1316. This exemplary implementation is partially shown in FIG. 32 and explained in FIGS. 30 and 31.

FIGS. 30 and 31 set forth color/tint-explanation screen shots 3000 and 3100 and show an exemplary implementation of the video explanations 332. This implementation of the video explanations 332 explains, in part, how to use the exemplary implementation of the color/tint video 1316 shown in FIG. 32.

FIG. 32 sets forth a color/tint-video screen shot 3200 of the exemplary implementation of the color/tint video 1316 of FIG. 13. The moving, photo-realistic objects include: a pale woman 3202; a medium woman 3204; and a red woman 3206.

The skin tone of each of the women 3202, 3204, and 3206 is carefully designed to aid the user in calibrating his display's color/tint parameter. These photo-realistic objects do so by each having the same hue, though with a different hue intensity. Thus, the hue is constant but the intensity is different, which allows the women's skin to appear hyper-sensitive and unrealistic for small color/tint changes.

Thus, at least one of these women 3202, 3204, and 3206 will appear unrealistic if a display's color/tint is adjusted outside of an optimum range. When the color/tint is turned only very slightly too low, the pale woman 3202 appears too pale, unrealistically so. When the color/tint is turned slightly too high, the red woman 3206 appears too red, unrealistically so. The medium woman 3204 provides a control to the user—she is less affected by changes to this parameter—allowing the user to relate color/tint changes to a more common Caucasian skin tone.

The Sharpness Video 1318

The sharpness video 1318 is designed to aid a user in optimizing a sharpness parameter for his or her display. The sharpness video 1318 can be used with a 4×3- or 16×9-shaped display and a CRT- or non-CRT-type display that has a TV connection type.

The sharpness video 1318 has a photo-realistic sharp-edged object that aids a user by having a sharpness such that adjusting a sharpness calibration of a user's display outside of an optimum range causes the object to appear unrealistic to the user.

In another implementation, the sharpness video's 1318 photo-realistic object aids a user by being hyper-sensitive to adjustments in the sharpness calibration of the user's display.

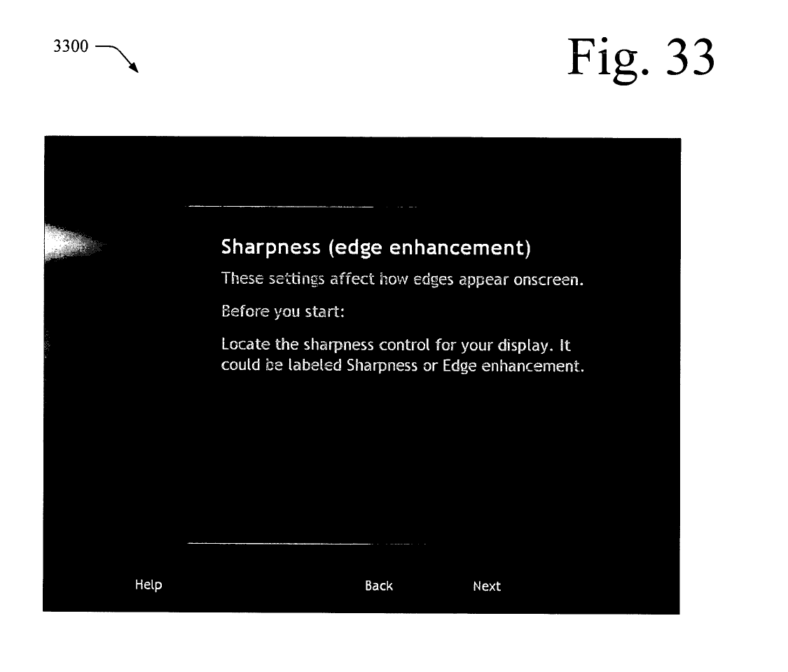

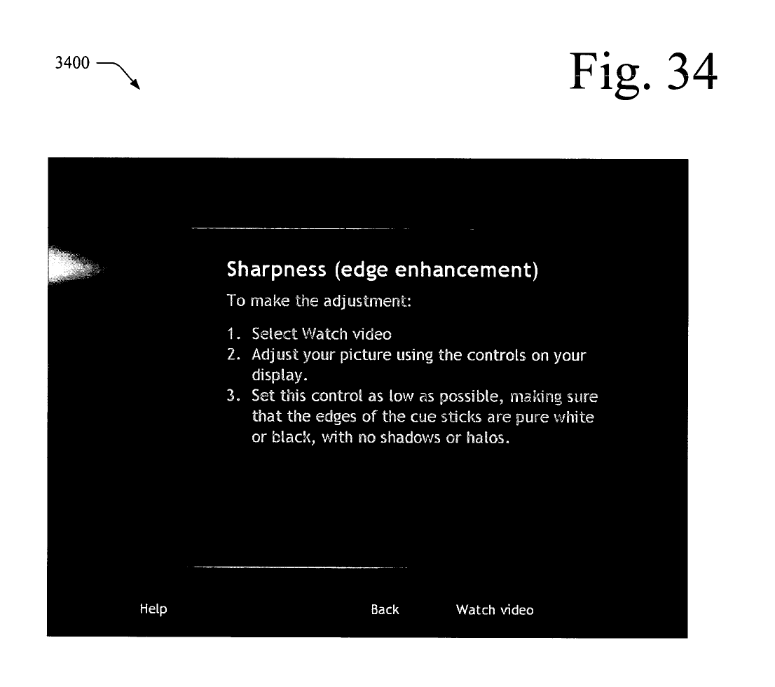

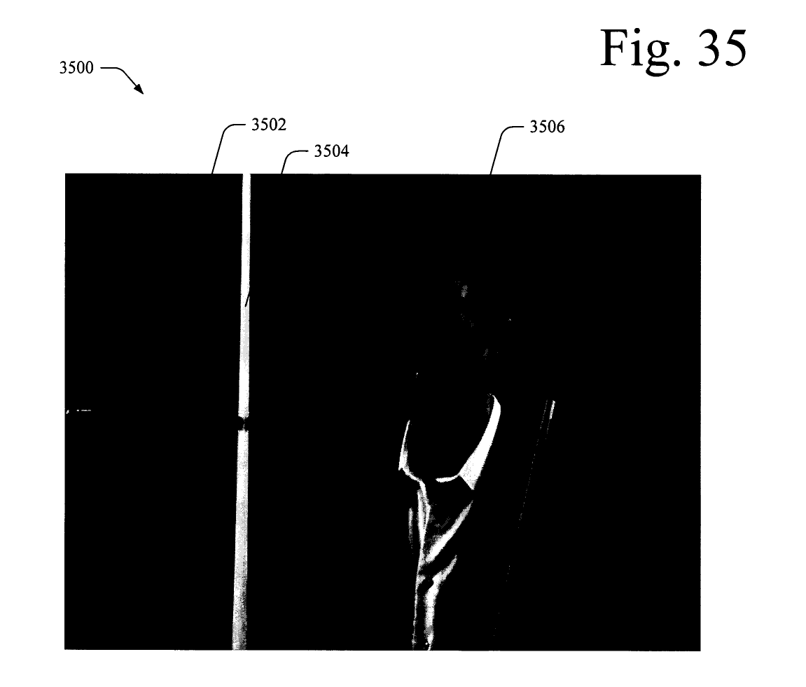

An example of a photo-realistic object that appears unrealistic even for small sharpness changes is shown in an exemplary implementation of the sharpness video 1318. This exemplary implementation is partially shown in FIG. 35 and explained in FIGS. 33 and 34.

FIGS. 33 and 34 set forth sharpness-explanation screen shots 3300 and 3400 and show an exemplary implementation of the video explanations 332. This implementation of the video explanations 332 explains how to use the exemplary implementation of the sharpness video 1318 shown in FIG. 35.

FIG. 35 sets forth a sharpness-video screen shot 3500 of the exemplary implementation of the sharpness video 1318 of FIG. 13. The exemplary implementation includes two photo-realistic sharp-edged objects, a black pool cue 3502 and a white pool cue 3504. The pool cues 3502 and 3504 are designed to show false edges or halos at or near their sharp edges for small change above the optimum sharpness range. The pool cues 3502 and 3504 are designed to appear fuzzy, with unrealistically soft edges for a small change below the optimum sharpness range.

This exemplary implementation shown in FIG. 35 also has a color, photo-realistic object, a male pool player 3506. The male pool player 3506 gives the user a real-life, photo-realistic color object that is also affected by changes to the sharpness parameter. This object helps the user relate changes to the sharpness parameter to a real-life object, which makes adjusting the parameter easier and more intuitive for the user.

Presenting the Instructions

After tailoring the instructions 328, the system 300 presents all or part of them to the user. If a user wants to calibrate only a brightness parameter of his or her display, for instance, the user can select the part of the tailored instructions 328 that are pertinent to calibrating that parameter.

In another implementation, the system 300 presents with a menu various parameters that the user may wish to calibrate. The user can select to view the instructions 328 for all of the parameters or certain ones of them.

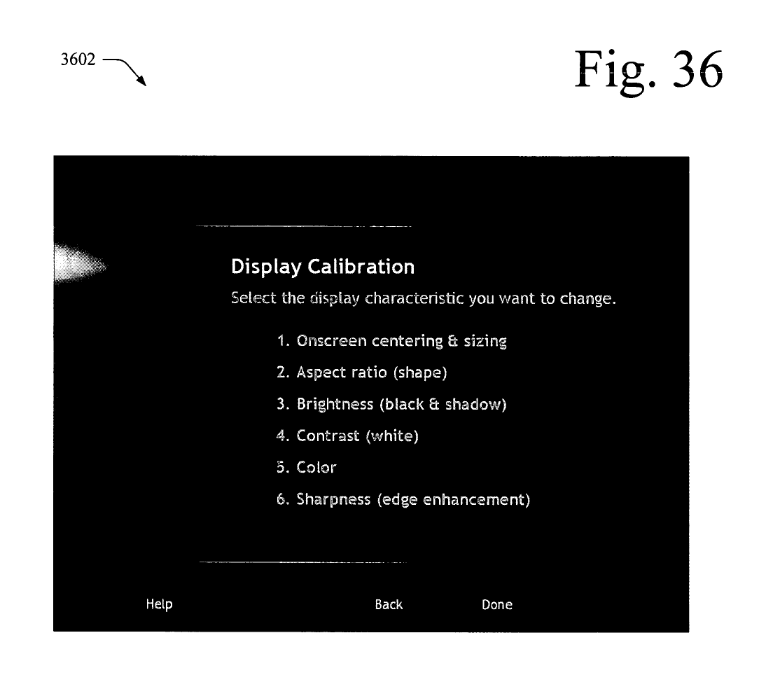

FIG. 36 sets forth a display calibration menu 3602. This menu 3602 sets forth six parameters from which a user can select. For each parameter selected, the system 300 will present instructions to aid the user in calibrating that parameter. The instructions (such as the tailored version of the instructions 328) can include the motion videos 330 shown in FIG. 13 or other types of instructions.

In some cases, the system 300 determines screen settings for the user's display. If these screen settings do not match screen settings appropriate for the user's type of display, the system 300 can direct the user to or install a screen settings application (not shown) to change the screen settings. The system 300 can do so prior to presenting the tailored instructions 328 to the user, which can further aid a user in more easily calibrating his or her display.

A Computer System

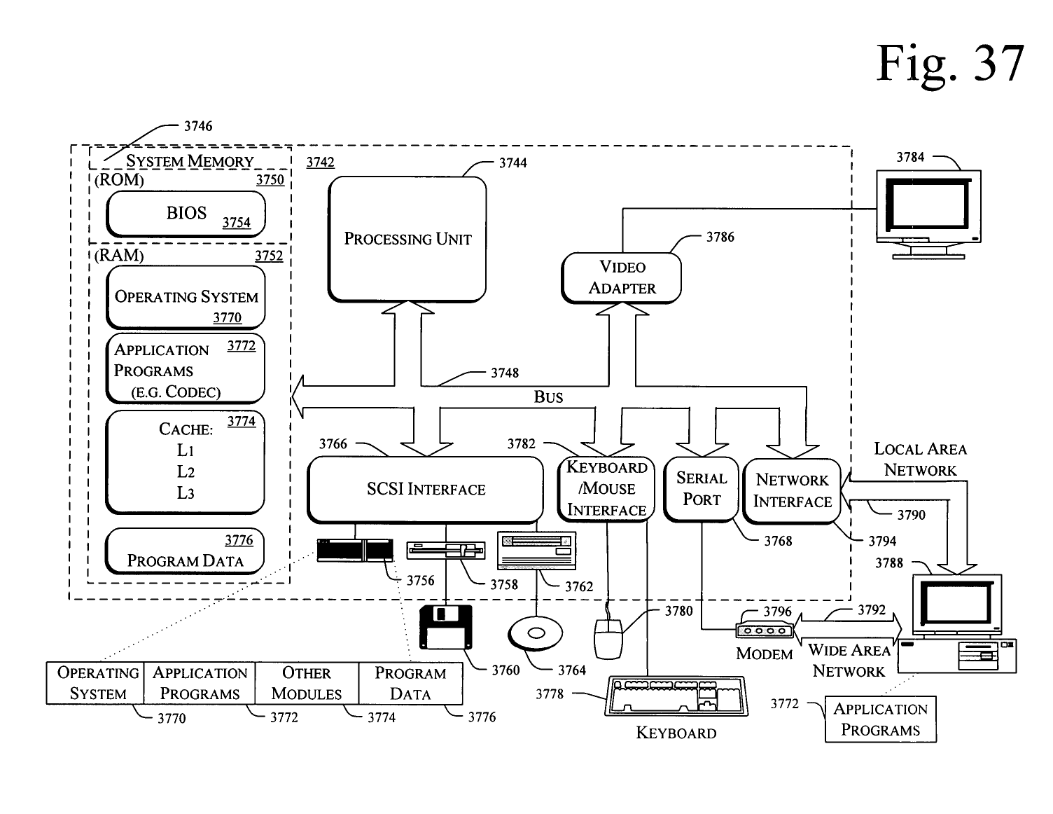

FIG. 37 shows an exemplary computer system that can be used to implement the processes described herein. Computer 3742 includes one or more processors or processing units 3744, a system memory 3746, and a bus 3748 that couples various system components including the system memory 3746 to processors 3744. The bus 3748 represents one or more of any of several types of bus structures, including a memory bus or memory controller, a peripheral bus, an accelerated graphics port, and a processor or local bus using any of a variety of bus architectures. The system memory 3746 includes read only memory (ROM) 3750 and random access memory (RAM) 3752. A basic input/output system (BIOS) 3754, containing the basic routines that help to transfer information between elements within computer 3742, such as during start-up, is stored in ROM 3750.

Computer 3742 further includes a hard disk drive 3756 for reading from and writing to a hard disk (not shown), a magnetic disk drive 3758 for reading from and writing to a removable magnetic disk 3760, and an optical disk drive 3762 for reading from or writing to a removable optical disk 3764 such as a CD ROM or other optical media. The hard disk drive 3756, magnetic disk drive 3758, and optical disk drive 3762 are connected to the bus 3748 by an SCSI interface 3766 or some other appropriate interface. The drives and their associated computer-readable media provide nonvolatile storage of computer-readable instructions, data structures, program modules and other data for computer 3742. Although the exemplary environment described herein employs a hard disk, a removable magnetic disk 3760 and a removable optical disk 3764, it should be appreciated by those skilled in the art that other types of computer-readable media which can store data that is accessible by a computer, such as magnetic cassettes, flash memory cards, digital video disks, random access memories (RAMs), read only memories (ROMs), and the like, may also be used in the exemplary operating environment.

A number of program modules may be stored on the hard disk 3756, magnetic disk 3760, optical disk 3764, ROM 3750, or RAM 3752, including an operating system 3770, one or more application programs 3772 (such as the display calibration engine 322 of FIG. 3), other program modules 3774, and program data 3776. A user may enter commands and information into computer 3742 through input devices such as a keyboard 3778 and a pointing device 3780. Other input devices (not shown) may include a microphone, joystick, game pad, satellite dish, scanner, or the like. These and other input devices are connected to the processing unit 3744 through an interface 3782 that is coupled to the bus 3748. A monitor 3784 or other type of display device is also connected to the bus 3748 via an interface, such as a video adapter 3786. In addition to the monitor, personal computers typically include other peripheral output devices (not shown) such as speakers and printers.

Computer 3742 commonly operates in a networked environment using logical connections to one or more remote computers, such as a remote computer 3788. The remote computer 3788 may be another personal computer, a server, a router, a network PC, a peer device or other common network node, and typically includes many or all of the elements described above relative to computer 3742. The logical connections depicted in FIG. 37 include a local area network (LAN) 3790 and a wide area network (WAN) 3792. Such networking environments are commonplace in offices, enterprise-wide computer networks, intranets, and the Internet.

When used in a LAN networking environment, computer 3742 is connected to the local network through a network interface or adapter 3794. When used in a WAN networking environment, computer 3742 typically includes a modem 3796 or other means for establishing communications over the wide area network 3792, such as the Internet. The modem 3796, which may be internal or external, is connected to the bus 3748 via a serial port interface 3768. In a networked environment, program modules depicted relative to the personal computer 3742, or portions thereof, may be stored in the remote memory storage device. It will be appreciated that the network connections shown are exemplary and other means of establishing a communications link between the computers may be used.

Generally, the data processors of computer 3742 are programmed by means of instructions stored at different times in the various computer-readable storage media of the computer. Programs and operating systems are typically distributed, for example, on floppy disks or CD-ROMs. From there, they are installed or loaded into the secondary memory of a computer. At execution, they are loaded at least partially into the computer's primary electronic memory. The invention described herein includes these and other various types of computer-readable storage media when such media contain instructions or programs for implementing the blocks described herein in conjunction with a microprocessor or other data processor. The invention also includes the computer itself when programmed according to the methods and techniques described herein.

For purposes of illustration, programs and other executable program components such as the operating system are illustrated herein as discrete blocks, although it is recognized that such programs and components reside at various times in different storage components of the computer, and are executed by the data processor(s) of the computer.

Conclusion

The above-described system and method enables a user to easily and intuitively calibrate his or her display. The system and method enables a user to calibrate a display by presenting instructions to the user that are based on the type of display that the user is attempting to calibrate. It also enables a user to more easily and intuitively calibrate his or her display by presenting a motion video tailored to help the user calibrate a parameter of the display. Although the invention has been described in language specific to structural features and/or methodological acts, it is to be understood that the invention defined in the appended claims is not necessarily limited to the specific features or acts described. Rather, the specific features and acts are disclosed as exemplary forms of implementing the claimed invention.

1. One or more computer-readable media comprising computer-executable instructions that perform the following when executed by a computer:
determine a type or a connection type of a display in use by a computer; and
present, based on the type or the connection type of the display, instructions to aid a user in calibrating the display.

2. The computer-readable media of claim 1, wherein the determination includes presenting graphics that illustrate multiple display types and receiving a selection of one of the multiple display types, wherein the selected display type is the type of the display in use by the computer.

3. The computer-readable media of claim 1, wherein the determination includes presenting graphics that illustrate multiple connection types and receiving a selection of one of the multiple connection types, wherein the presentation is based on the selected connection type.

4. The computer-readable media of claim 1, wherein the determination includes only the type of the display and the presentation is based on only the type of the display.

5. The computer-readable media of claim 1, wherein the determination includes presenting multiple connection types to the user and receiving, from the user, a selection of one of the connection types.

6. The computer-readable media of claim 1, wherein the determination includes presenting a television connection type and a computer connection type to the user and receiving, from the user, a selection of the television connection type or the computer connection type.

7. The computer-readable media of claim 1, wherein the determination includes presenting multiple types of displays to the user and receiving, from the user, a selection of one of the display types.

8. The computer-readable media of claim 1, wherein the determination includes presenting multiple types of displays to the user and receiving, from the user, a selection of one of the display types, wherein the multiple types of displays include a tube type of display, a panel type of display, a rear-projection type of display, or a forward-projection type of display.

9. The computer-readable media of claim 1, wherein the determination includes presenting multiple types of displays to the user and receiving, from the user, a selection of one of the display types, wherein the multiple display types include a tube type of display, a plasma-panel type of display, a non-plasma-panel type of display, a CRT rear-projection type of display, a non-CRT rear-projection type of display, a three-light forward-projection type of display, or a one-light forward-projection type of display.

10. The computer-readable media of claim 1, wherein the determination includes presenting a 4×3 width-to-height ratio and a 16×9 width-to-height ratio to the user, and receiving, from the user, a selection of one of the width-to-height ratios.

11. The computer-readable media of claim 1, wherein the presentation of the instructions is directed to calibrating the display for use of the display to render motion video.

12. The computer-readable media of claim 1, wherein the presentation of the instructions is directed to calibrating displays having a television connection type.

13. The computer-readable media of claim 1, wherein the presentation of the instructions is directed to calibrating displays having a computer connection type.

14. The computer-readable media of claim 1, wherein the presentation of the instructions is directed to calibrating a tube-type display if the display is of the tube-type.

15. The computer-readable media of claim 1, wherein the presentation of the instructions is directed to calibrating a panel-type display if the display is of the panel-type.

16. The computer-readable media of claim 1, wherein the presentation of the instructions is directed to calibrating a rear-projector-type display if the display is of the rear-projector-type.

17. The computer-readable media of claim 1, wherein the presentation of the instructions is directed to calibrating a forward-projector-type display if the display is of the forward-projector-type.

18. The computer-readable media of claim 1, wherein the presentation of the instructions includes presenting a photo-realistic moving video.

19. The computer-readable media of claim 1, wherein the presentation of the instructions includes presenting a photo-realistic moving video and information directed at how the photo-realistic moving video guides the user in calibrating the display.

20. The computer-readable media of claim 1, wherein the presentation of the instructions is directed at aiding the user to calibrate a centering and size of media on the display.

21. The computer-readable media of claim 1, wherein the presentation of the instructions is directed at aiding the user to calibrate a brightness of the display.

22. The computer-readable media of claim 1, wherein the presentation of the instructions is directed at aiding the user to calibrate a contrast of the display.

23. The computer-readable media of claim 1, wherein the presentation of the instructions is directed at aiding the user to calibrate a color balance of the display.

24. The computer-readable media of claim 1, wherein the presentation of the instructions is directed at aiding the user to calibrate a color and tint of the display.

25. The computer-readable media of claim 1, wherein the presentation of the instructions is directed at aiding the user to calibrate a sharpness of the display.

26. The computer-readable media of claim 1, wherein the presentation of the instructions includes presenting a photo-realistic moving video tailored to centering and sizing of media on the display.

27. The computer-readable media of claim 1, wherein the presentation of the instructions includes presenting a photo-realistic moving video tailored to calibrating a brightness of the display.

28. The computer-readable media of claim 1, wherein the presentation of the instructions includes presenting a photo-realistic moving video tailored to calibrating a contrast of the display.

29. The computer-readable media of claim 1, wherein the presentation of the instructions includes presenting a photo-realistic moving video tailored to calibrating a color balance of the display.

30. The computer-readable media of claim 1, wherein the presentation of the instructions includes presenting a photo-realistic moving video tailored to calibrating a color and tint of the display.

31. The computer-readable media of claim 1, wherein the presentation of the instructions includes presenting a photo-realistic moving video tailored to calibrating a sharpness of the display.

32. The computer-readable media of claim 1, further comprising:
directing the user to a screen settings application if the type of the display in use by the computer does not match screen settings appropriate for the type of the display.

33. The computer-readable media of claim 1, further comprising:
installing a screen settings application if the type of the display in use by the computer does not match screen settings appropriate for the type of the display.

34. One or more computer-readable media comprising computer-executable instructions that perform the following when executed by a computer:
present one or more photo-realistic motion videos to a user to aid the user in calibrating a computer display.

35. The computer-readable media of claim 34, wherein the photo-realistic motion videos are presented based on the computer display's type of display.

36. The computer-readable media of claim 34, wherein the photo-realistic motion videos are presented based on the computer display's connection type.

37. The computer-readable media of claim 34, wherein one or more of the photo-realistic motion videos are hyper-sensitive to calibration changes of the computer display.

38. The computer-readable media of claim 34, wherein the presentation is directed to calibrating the computer display for use of the computer display to render motion video.

39. The computer-readable media of claim 34, wherein the presentation is directed to calibrating a tube-type display if the computer display is of the tube-type.

40. The computer-readable media of claim 34, wherein the presentation is directed to calibrating a panel-type display if the computer display is of the panel-type.

41. The computer-readable media of claim 34, wherein the presentation is directed to calibrating a rear-projector-type display if the computer display is of the rear-projector-type.

42. The computer-readable media of claim 34, wherein the presentation is directed to calibrating a forward-projector-type display if the computer display is of the forward-projector-type.

43. The computer-readable media of claim 34, wherein the presentation includes information directed at how the photo-realistic moving videos guide the user in calibrating the computer display.

44. The computer-readable media of claim 34, wherein the presentation is directed at aiding the user to calibrate a centering and size of media on the computer display.

45. The computer-readable media of claim 34, wherein the presentation is directed at aiding the user to calibrate a brightness of the computer display.

46. The computer-readable media of claim 34, wherein the presentation is directed at aiding the user to calibrate a contrast of the computer display.

47. The computer-readable media of claim 34, wherein the presentation is directed at aiding the user to calibrate a color balance of the computer display.

48. The computer-readable media of claim 34, wherein the presentation is directed at aiding the user to calibrate a color and tint of the computer display.

49. The computer-readable media of claim 34, wherein the presentation is directed at aiding the user to calibrate a sharpness of the computer display.

50. The computer-readable media of claim 34, wherein one of the photo-realistic-motion videos is tailored to centering and sizing of media on the computer display.

51. The computer-readable media of claim 34, wherein one of the photo-realistic-motion videos is tailored to calibrating a brightness of the computer display.

52. The computer-readable media of claim 34, wherein one of the photo-realistic-motion videos is tailored to calibrating a contrast of the computer display.

53. The computer-readable media of claim 34, wherein one of the photo-realistic-motion videos is tailored to calibrating a color balance of the computer display.

54. The computer-readable media of claim 34, wherein one of the photo-realistic-motion videos is tailored to calibrating a color and tint of the computer display.

55. The computer-readable media of claim 34, wherein one of the photo-realistic-motion videos is tailored to calibrating a sharpness of the computer display.

56. A method comprising:
determining a type of a display; and
presenting, based on the type of the display, one or more photo-realistic motion videos to aid a user in calibrating the display.

57. The method of claim 56, wherein the determining includes presenting graphics that illustrate multiple types of displays and receiving a selection of the type of the display from the multiple types of displays.

58. The method of claim 56, further comprising:
determining a connection type of the display, and
wherein the presenting is also based on the connection type of the display.

59. The method of claim 58, wherein the determining the connection type of the display includes presenting graphics that illustrate multiple connection types and receiving a selection of the connection type of the display from the multiple connection types.

60. The method of claim 56, wherein one of the photo-realistic motion videos is hyper-sensitive to calibration changes of the display.

61. The method of claim 56, wherein the determining includes presenting multiple types of displays to the user and receiving, from the user, a selection of the type of the display.

62. The method of claim 56, wherein the determining includes presenting multiple types of displays to the user and receiving, from the user, a selection of the type of the display, wherein the multiple types of displays include a tube type of display, a panel type of display, a rear-projection type of display, or a forward-projection type of display.

63. The method of claim 56, wherein the determining includes presenting multiple types of displays to the user and receiving, from the user, a selection of the type of the display, wherein the multiple types of displays include a tube type of display, a plasma-panel type of display, a non-plasma panel type of display, a CRT rear-projection type of display, a non-CRT rear-projection type of display, a three-light forward-projection type of display, or a one-light forward-projection type of display.

64. The method of claim 56, wherein the presenting is directed to calibrating the display for use of the display to render motion video.

65. The method of claim 56, wherein the display is in use by a computer and further comprising directing the user to a screen settings application if the type of the display in use by the computer does not match screen settings appropriate for the type of the display.

66. The method of claim 56, wherein the display is in use by a computer and further comprising installing a screen settings application if the type of the display in use by the computer does not match screen settings appropriate for the type of the display.

67. One or more computer-readable media comprising computer-executable instructions that perform the following when executed by a computer:
present instructions to a user to aid the user in calibrating a computer display of a particular type, wherein the instructions presented are tailored to aid calibration of computer displays of that particular type.

68. A photo-realistic motion video capable of aiding a user to optimally calibrate a parameter of a video display.

69. The photo-realistic motion video of claim 68, wherein the photo-realistic motion video is hypersensitive to a calibration change to the parameter.

70. The photo-realistic motion video of claim 68, wherein the parameter affects centering of media on the video display.

71. The photo-realistic motion video of claim 68, wherein the parameter affects sizing of media on the video display.

72. The photo-realistic motion video of claim 68, wherein the parameter affects an aspect ratio of the video display.

73. The photo-realistic motion video of claim 68, wherein the parameter affects a brightness of the video display.

74. The photo-realistic motion video of claim 68, wherein the parameter affects a contrast of the video display.

75. The photo-realistic motion video of claim 68, wherein the parameter affects a color balance of the video display.

76. The photo-realistic motion video of claim 68, wherein the parameter affects a color and tint of the video display.

77. The photo-realistic motion video of claim 68, wherein the parameter affects a sharpness of the video display.

78. A photo-realistic motion video capable of being rendered on a computer display and having a photo-realistic object, the object having a hue such that adjusting a hue saturation of the computer display outside of an optimum range causes the object to appear unrealistic to a user.

79. The photo-realistic motion video of claim 78, wherein the photo-realistic object is hyper-sensitive to adjustments in the hue saturation of the computer display.

80. The photo-realistic motion video of claim 78, wherein the motion video includes two or more photo-realistic objects, the objects each having a similar hue and a dissimilar hue intensity such that adjusting the hue saturation of the computer display causes one of the objects to appear unrealistic to the user if the hue saturation is adjusted above the optimum range and another one of the objects to appear unrealistic to the user if the hue saturation is adjusted below the optimum range.

81. The photo-realistic motion video of claim 78, wherein the motion video includes three or more photo-realistic objects, the objects each having a similar hue and a dissimilar hue intensity such that adjusting the hue saturation of the computer display causes one of the objects to appear unrealistic to the user if the hue saturation is adjusted above the optimum range, another of the objects to appear unrealistic to the user if the hue saturation is adjusted below the optimum range, and another of the objects to appear slightly unrealistic to the user if the hue saturation is adjusted outside of the optimum range.

82. The photo-realistic motion video of claim 78, wherein the object is a moving human being.

83. The photo-realistic motion video of claim 78, wherein the adjusting the saturation outside of the optimum range causes the object to appear unrealistic to unaided eyes of the user.

84. The photo-realistic motion video of claim 78, further comprising instructions directed at using the motion video as an aid in calibrating the hue saturation of the computer display.

85. The photo-realistic motion video of claim 78, wherein the motion video is tailored to a cathode-ray-tube type of computer display.

86. A photo-realistic image capable of being rendered on a computer display and having a photo-realistic object, the object having a brightness such that adjusting a brightness calibration of the computer display outside of an optimum range causes the object to appear unrealistic to a user.

87. The photo-realistic image of claim 86, wherein the photo-realistic object is hyper-sensitive to adjustments in the brightness calibration of the computer display.

88. The photo-realistic image of claim 86, wherein the image includes a dark-gray area and a black area, the dark-gray area becoming undistinguishable from the black area if the brightness calibration is adjusted below the optimum range.

89. The photo-realistic image of claim 86, wherein the image is a motion video.

90. The photo-realistic image of claim 86, wherein the photo-realistic object simulates a PLUGE test pattern.

91. The photo-realistic image of claim 86, wherein the image is a motion video and the photo-realistic object moves.

92. The photo-realistic image of claim 86, further comprising instructions directed at using the image as an aid in calibrating the brightness calibration of the computer display.

93. A motion video capable of being rendered on a computer display and having a photo-realistic object such that adjusting a contrast calibration of the computer display outside of an optimum range causes the object to appear unrealistic to a user.

94. The motion video of claim 93, wherein the photo-realistic object is hyper-sensitive to adjustments to the contrast calibration of the computer display.

95. The motion video of claim 93, wherein the photo-realistic object appears to bend or warp if the contrast calibration is adjusted outside of the optimum range.

96. The motion video of claim 93, wherein the photo-realistic object includes two areas having different appearances when the contrast calibration is within the optimum range and the two areas of the photo-realistic object are un-differentiable if the contrast calibration is adjusted below the optimum range.

97. The motion video of claim 93, wherein the photo-realistic object includes two areas having different appearances when the contrast calibration is within the optimum range and the two areas of the photo-realistic object are un-differentiable if the contrast calibration is adjusted above the optimum range.

98. The motion video of claim 93, further comprising instructions directed at using the motion video as an aid in calibrating the contrast calibration of the computer display.

99. The motion video of claim 93, wherein the motion video is substantially photo-realistic.

100. A photo-realistic motion video capable of being rendered on a computer display and having a photo-realistic sharp-edged object, the sharp-edged object having edges such that adjusting a sharpness calibration of the computer display outside of an optimum range causes the edges of the object to appear unrealistic to a user.

101. The motion video of claim 100, wherein the photo-realistic sharp-edged object is hyper-sensitive to adjustments to the sharpness calibration of the computer display.

102. The motion video of claim 100, further comprising a second, commonly understood and photo-realistic object usable as a control to show how adjusting the sharpness calibration affects a commonly understood object.

103. The motion video of claim 100, wherein the sharp-edged object appears to have false or additional edges if the sharpness calibration is adjusted above the optimum range.

104. The motion video of claim 100, wherein the sharp-edged object appears to have unrealistically soft edges if the sharpness calibration is adjusted below the optimum range.

105. The motion video of claim 100, wherein the sharp-edged object appears to have false or additional edges if the sharpness calibration is adjusted above the optimum range and unrealistically soft edges if the sharpness calibration is adjusted below the optimum range.

106. The motion video of claim 100, further comprising instructions directed at using the motion video as an aid in calibrating the sharpness calibration of the computer display.

107. A system comprising:
a display having a screen capable of displaying display-type options;
a user-input device capable of enabling a user to select one of the display-type options;
a display calibration application capable of receiving the selected display-type option and determining instructions to aid the user in calibrating the display based on the selected display-type option, wherein the display is further capable of displaying the instructions; and
a computer capable of executing the display calibration application.

108. The system of claim 107, wherein the instructions include one or more photo-realistic motion videos.

109. A method comprising:
presenting graphics that illustrate multiple display types;
receiving a selection of one of the multiple display types; and
presenting, based on the selected display type, instructions to aid a user in calibrating a display of the selected display type.

110. The method of claim 109, further comprising:
presenting second graphics that illustrate multiple display connection types; and
receiving a second selection of one of the multiple display connection types,
wherein the presenting is further based on the selected display connection type.

111. The method of claim 110, wherein the multiple connection types include a television connection type and a computer connection type.

112. The method of claim 110, further comprising:
presenting text describing the multiple display connection types.

113. The method of claim 109, further comprising:
presenting second graphics that illustrate multiple aspect ratios; and
receiving a second selection of one of the multiple aspect ratios,
wherein the presenting is further based on the selected aspect ratio.

114. The method of claim 113, wherein the multiple aspect ratios include a standard and a widescreen aspect ratio.

115. The method of claim 113, further comprising:
presenting text describing the multiple aspect ratios.

116. The method of claim 109, further comprising:
enabling a user to select one of the multiple display types.

117. The method of claim 109, further comprising:
presenting text describing the multiple display types.

118. The method of claim 109, wherein the presenting instructions is directed to calibrating the display for use of the display to render motion video.

119. The method of claim 109, wherein the multiple display types include a tube type of display, a panel type of display, a rear-projection type of display, or a forward-projection type of display.

120. The method of claim 109, wherein the multiple display types include a tube type of display, a plasma-panel type of display, a non-plasma-panel type of display, a CRT rear-projection type of display, a non-CRT rear-projection type of display, a three-light forward-projection type of display, or a one-light forward-projection type of display.

121. The method of claim 109, wherein the presenting instructions includes presenting a photo-realistic moving video.

122. The method of claim 109, wherein the presenting instructions includes presenting a photo-realistic moving video and information directed at how the photo-realistic moving video guides the user in calibrating the display.

123. An apparatus comprising:
means for determining a type or a connection type of a display in use by a computer; and
means for presenting, based on the type or the connection type of the display, instructions to aid a user in calibrating the display.

124. The apparatus of claim 123, wherein the instructions include one or more photo-realistic motion videos.
